(19) United States
(12) Patent Application Publication
(10) Pub. No.: US 2026/0265899 A1
(43) Pub. Date: Sep. 10, 2026

(54) DEPOSITION MASK, METHOD OF MANUFACTURING THE SAME, AND ELECTRONIC DEVICE MANUFACTURED BY THE DEPOSITION MASK

(71) Applicant: Samsung Display Co., LTD., Yongin-si (KR)

(72) Inventor: Sung Woon KIM, Yongin-si (KR)

(21) Appl. No.: 19/369,779

(22) Filed: Oct. 27, 2025

(30) Foreign Application Priority Data
Mar. 7, 2025 (KR) 10-2025-0029785

(51) Int. Cl. C23C 14/04; H10K 59/12; H10K 71/16; H10K 50/19

(52) U.S. Cl. CPC C23C 14/042; H10K 59/1201; H10K 71/166; H10K 50/19

(57) ABSTRACT

A deposition mask includes a mask substrate, and a membrane disposed on the mask substrate. Cell openings penetrate the mask substrate, and pixel openings penetrate the membrane. The pixel openings have an axial tilt that increases in a direction from a center of the membrane toward an edge portion of the membrane.

### CROSS REFERENCE TO RELATED APPLICATIONS

This application claims priority to Korean Patent Application No. 10-2025-0029785, filed on Mar. 7, 2025, and all the benefits accruing therefrom under 35 U.S.C. §119, the content of which in its entirety is herein incorporated by reference.

### BACKGROUND

### 1. Field

The disclosure relates to a deposition mask, a method of manufacturing the same, and an electronic device manufactured by the same.

### 2. Description of the Related Art

Wearable devices in which a focus is formed at a distance close to user’s eyes have been developed in the form of glasses or a helmet. The wearable device may provide an augmented reality (“AR”) screen or a virtual reality (“VR”) screen to a user. For example, the wearable device may be a head mounted display (“HMD”) device or AR glasses.

In the case of wearable devices such as the HMD device or the AR glasses, a display specification of approximately 3000 pixels per inch (PPI) or higher is desired to allow users to use them for a long time without symptoms of dizziness. To this end, organic light-emitting diode on silicon (“OLEDoS”) technology is emerging for use in a high-resolution relatively small organic light-emitting display device. The OLEDoS is a technology in which organic light-emitting diodes (“OLED”) are arranged on a semiconductor substrate on which complementary metal oxide semiconductor (“CMOS”) elements are arranged.

In order to manufacture a display panel with a relatively high resolution of about 3000 PPI or higher, a high-resolution deposition mask is desired. For example, the deposition mask may be manufactured by forming a membrane in which a plurality of pixel openings is defined on a mask substrate, and partially removing the mask substrate to define cell openings that expose the pixel openings. The pixel openings may be defined by forming the membrane on the mask substrate and then performing an anisotropic etching process such as a reactive ion etching (“RIE”) process.

### SUMMARY

A deposition mask may be used in a deposition process for forming light-emitting layers on a backplane substrate. In the deposition process, the backplane substrate may be disposed on the deposition mask, and a deposition source for providing a vapor deposition material may be disposed under the deposition mask. The vapor deposition material may be deposited on the backplane substrate through the pixel openings, thereby forming the light-emitting layers on the backplane substrate. In this case, the distance between the deposition source and the pixel openings may increase from the center of the deposition mask in the radial direction, and the incident angle of the deposition material provided onto the backplane substrate may increase from the center of the backplane substrate in the radial direction. For example, when the deposition source is disposed below the center portion of the deposition mask, shadow areas may increase from the center of the backplane substrate in the radial direction. Therefore, the sizes and positions of the light-emitting layers may become non-uniform, and the pixel position accuracy (“PPA”) of the light-emitting layers may be degraded.

Advantages and features of embodiments of the disclosure provide a deposition mask capable of reducing shadow areas, a method of manufacturing the same, and an electronic device manufactured by the same.

However, embodiments of the disclosure are not limited to those set forth herein. The above and other embodiments of the disclosure will become more apparent to one of ordinary skill in the art to which the disclosure pertains by referencing the detailed description of the disclosure given below.

In an embodiment of the disclosure, a deposition mask may include a mask substrate and a membrane disposed on the mask substrate. Cell openings penetrate the mask substrate, and pixel openings penetrate the membrane. The pixel openings may have an axial tilt that increases in a direction from a center of the membrane toward an edge portion of the membrane.

In an embodiment, the membrane may include mask cell regions respectively arranged on the cell openings. A plurality of pixel openings may be defined in each of the mask cell regions, and the plurality of pixel openings may have an axial tilt that gradually increases in the direction from the center of the membrane toward the edge portion of the membrane.

In an embodiment, in each of the mask cell regions, a gap between upper portions of the plurality of pixel openings may be greater than a gap between lower portions of the plurality of pixel openings.

In an embodiment, an axial tilt of pixel openings of a mask cell region next (adjacent) to the edge portion of the membrane may be greater than an axial tilt of pixel openings of a mask cell region next (adjacent) to the center of the membrane.

In an embodiment, the pixel openings may have a constant width in an extension direction of each of the pixel openings.

In an embodiment, the deposition mask may further include a buffer inorganic film disposed between the mask substrate and the membrane and buffer openings connecting the cell openings to the pixel openings may be defined in the buffer inorganic film.

In an embodiment, the deposition mask may further include a rear inorganic film disposed on a rear surface of the mask substrate. The membrane may be disposed on a front surface of the mask substrate, and rear openings connected to the cell openings may be defined in the rear inorganic film.

In an embodiment of the disclosure, a method of manufacturing a deposition mask may include forming a membrane on a mask substrate, defining pixel openings penetrating the membrane, and defining cell openings penetrating the mask substrate. The pixel openings may be defined to have an axial tilt that increases in a direction from a center of the membrane toward an edge portion of the membrane.

In an embodiment, the pixel openings may be defined by an anisotropic etching process.

In an embodiment, the defining the pixel openings may include bending the mask substrate such that the membrane becomes concave, and performing the anisotropic etching process such that the pixel openings are defined in a central axis direction of the mask substrate.

In an embodiment, during the anisotropic etching process, the mask substrate may be supported by a chuck having a top surface with a concave central portion.

In an embodiment, during the anisotropic etching process, the chuck may hold the mask substrate using an electrostatic force.

In an embodiment, the pixel openings may be defined to have a constant width in an extension direction of each of the pixel openings.

In an embodiment, the method may further include forming a buffer inorganic film on the mask substrate, and the membrane may be formed on the buffer inorganic film.

In an embodiment, the method may further include defining buffer openings connecting the cell openings to the pixel openings by partially removing the buffer inorganic film.

In an embodiment, each of the cell openings may be connected to a plurality of pixel openings. The plurality of pixel openings may be defined to have an axial tilt that gradually increases in the direction from the center of the membrane toward the edge portion of the membrane.

In an embodiment, each of the cell openings may be connected to a plurality of pixel openings, and a gap between upper portions of the plurality of pixel openings may be greater than a gap between lower portions of the plurality of pixel openings.

In an embodiment, the method may further include forming a rear inorganic film, in which rear openings are defined, on a rear surface of the mask substrate. The membrane may be formed on a front surface of the mask substrate, and the cell openings may be defined by an etching process using the rear inorganic film as an etching mask.

In an embodiment of the disclosure, an electronic device may include a display panel. The display panel may include a backplane substrate and a plurality of light-emitting layers formed on the backplane substrate by a deposition mask. The deposition mask may include a mask substrate, and a membrane disposed on the mask substrate. Cell openings may penetrate the mask substrate, and pixel openings may penetrate the membrane. The pixel openings may have an axial tilt that increases in a direction from a center of the membrane toward an edge portion of the membrane, and the plurality of light-emitting layers may be formed by a deposition process that provides a vapor deposition material through the cell openings and the pixel openings.

In an embodiment, the electronic device may further include at least one of a processor, a memory, and a power module.

By embodiments of the disclosure, in a deposition process for forming light-emitting layers on a backplane substrate, the incident angle of a vapor deposition material provided onto the backplane substrate may be approximately the same as or similar to an axial tilt of each of pixel openings. Accordingly, shadow areas may be decreased or removed in the deposition process, and the PPA and the size uniformity of the light-emitting layers may be greatly improved.

Other features and embodiments may be apparent from the following detailed description and the drawings.

### BRIEF DESCRIPTION OF THE DRAWINGS

The above and other advantages and features of the disclosure will become more apparent by describing in detail embodiments thereof with reference to the attached drawings, in which:

FIG. 1 is a block diagram of an embodiment of an electronic device according to the disclosure;

FIG. 2 is a schematic diagram of an embodiment of an electronic device according to the disclosure;

FIG. 3 is an exploded perspective view illustrating an embodiment of a display device according to the disclosure;

FIG. 4 is a block diagram illustrating the display device shown in FIG. 3;

FIG. 5 is an equivalent circuit diagram illustrating an embodiment of a first sub-pixel shown in FIG. 4;

FIG. 6 is a schematic plan view illustrating an embodiment of a display panel shown in FIG. 3;

FIG. 7 is a schematic enlarged plan view illustrating an embodiment of a display area shown in FIG. 6;

FIG. 8 is a schematic enlarged plan view illustrating another embodiment of the display area shown in FIG. 6;

FIG. 9 is a schematic cross-sectional view illustrating an embodiment of the display panel taken along line I1-I1' shown in FIG. 7;

FIG. 10 is a schematic cross-sectional view illustrating another embodiment of the display panel taken along line I1-I1' shown in FIG. 7;

FIG. 11 is a schematic cross-sectional view illustrating another embodiment of the display panel taken along line I1-I1' shown in FIG. 7;

FIG. 12 is a schematic perspective view illustrating one embodiment of a head mounted display;

FIG. 13 is a schematic exploded perspective view illustrating the head mounted display shown in FIG. 12;

FIG. 14 is a schematic perspective view illustrating another embodiment of a head mounted display;

FIG. 15 is a schematic diagram illustrating an embodiment of a deposition mask and a deposition apparatus including the deposition mask;

FIG. 16 is a schematic bottom view illustrating a backplane substrate shown in FIG. 15;

FIG. 17 is a schematic plan view illustrating a deposition mask shown in FIG. 15;

FIG. 18 is a schematic plan view illustrating mask cell region shown in FIG. 17;

FIG. 19 is a schematic cross-sectional view taken along line I2-I2' shown in FIG. 18;

FIG. 20 is a schematic cross-sectional view illustrating a membrane of the deposition mask shown in FIG. 17;

FIG. 21 is a schematic enlarged cross-sectional view illustrating pixel openings shown in FIG. 20;

FIG. 22 is a schematic diagram illustrating a method of forming light-emitting layers on a backplane substrate using the deposition mask shown in FIG. 17;

FIGS. 23 to 29 are diagrams illustrating an embodiment of a method of manufacturing a deposition mask according to the disclosure;

FIG. 23 is a schematic cross-sectional view illustrating formation of a buffer inorganic film and an intermediate inorganic film;

FIG. 24 is a schematic cross-sectional view illustrating formation of a membrane and a rear inorganic film;

FIG. 25 is a schematic cross-sectional view illustrating an operation of defining pixel openings;

FIG. 26 is a schematic diagram illustrating an etching apparatus for defining pixel openings;

FIG. 27 is a schematic cross-sectional view illustrating an operation of defining an intermediate opening and a rear opening;

FIG. 28 is a schematic cross-sectional view illustrating an operation of defining a cell opening; and

FIG. 29 is a schematic cross-sectional view illustrating an operation of defining a buffer opening.

### DETAILED DESCRIPTION

The disclosure will now be described more fully hereinafter with reference to the accompanying drawings, in which various embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when an element or a layer is referred to as being "on" another element or layer, it may be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" may mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments will be described in detail with reference to the accompanying drawings.

The display device in an embodiment of the disclosure may be applied to various electronic devices. The electronic device according to an embodiment of the disclosure includes the display device described above, and may further include modules or devices having additional functions in addition to the display device.

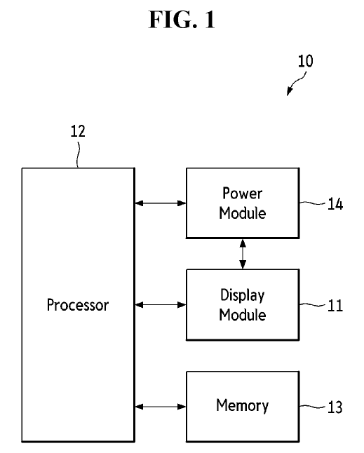

FIG. 1 is a block diagram of an embodiment of an electronic device according to the disclosure.

Referring to FIG. 1, the electronic device 10 in an embodiment of the disclosure may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery, and a power conversion module that converts the power supplied by the power supply module to generate power desired for the operation of the electronic device 10.

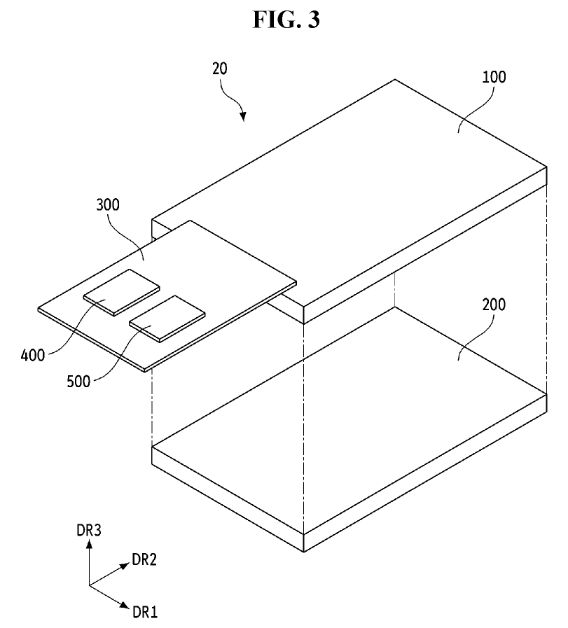

At least one of the components of the electronic device 10 according to an embodiment of the disclosure may be included in the display device 20 (refer to FIG. 3) in the embodiments of the disclosure. In addition, some modules of the individual modules functionally included in one module may be included in the display device 20, and other modules may be provided separately from the display device 20. In an embodiment, the display device 20 may include the display module 11, and the processor 12, the memory 13, and the power module 14 may be provided in the form of other devices within the electronic device 10 other than the display device 20.

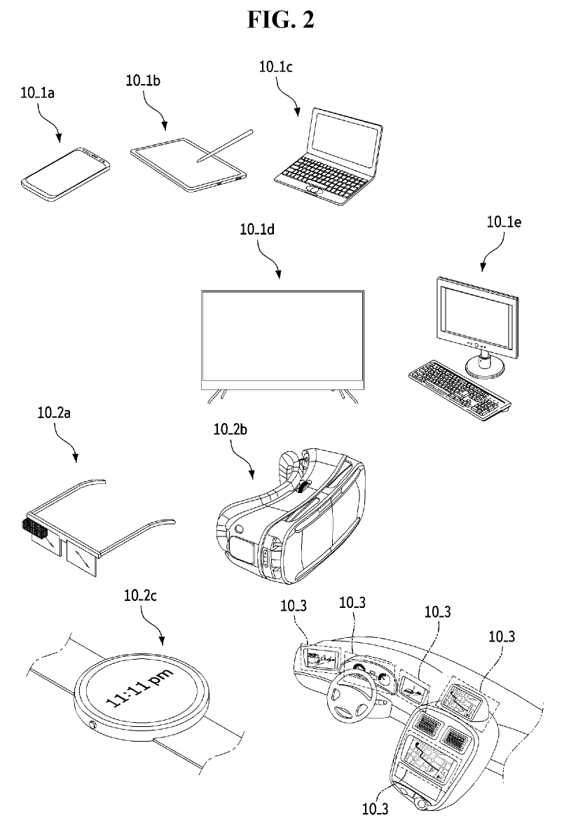

FIG. 2 is a schematic diagram of an embodiment of an electronic device according to the disclosure.

Referring to FIG. 2, various electronic devices to which display devices 20 in embodiments of the disclosure are applied may include not only image display electronic devices such as a smart phone 10_1a, a tablet personal computer (“PC”) 10_1b, a laptop 10_1c, a television (“TV”) 10_1d, and a desk monitor 10_1e, but also wearable electronic devices including display modules such as smart glasses 10_2a, a head mounted display 10_2b, and a smart watch 10_2c, and vehicle electronic devices 10_3 including display modules such as a Center Information Display (“CID”) and a room mirror display arranged on a dashboard, center fascia, and dashboard of an automobile.

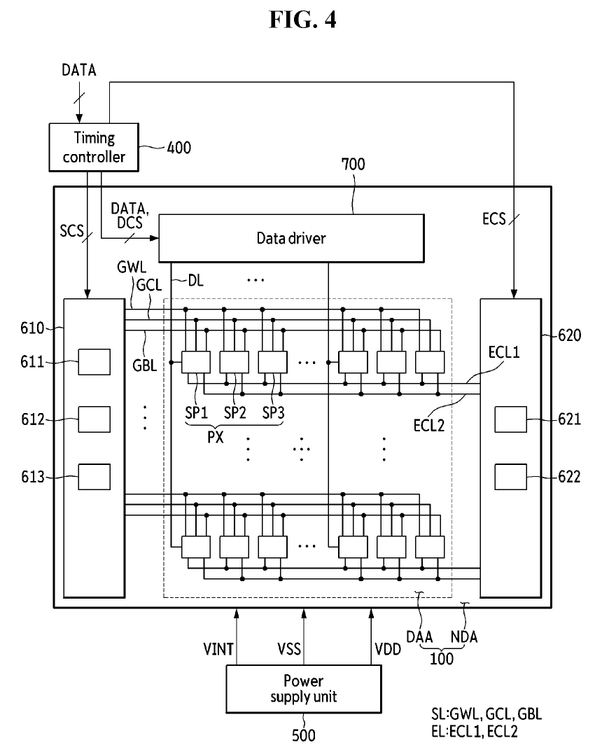

FIG. 3 is an exploded perspective view illustrating an embodiment of a display device according to the disclosure. FIG. 4 is a block diagram illustrating the display device shown in FIG. 3.

Referring to FIGS. 3 and 4, a display device 20 in an embodiment may be a device displaying a moving image or a still image. A display device 20 in an embodiment may be used as the electronic device 10 or the display module 11 of the electronic device 10. In an embodiment, the display device 20 in an embodiment may be applied to portable electronic devices 10 such as a mobile phone, a smartphone, a tablet personal computer, a mobile communication terminal, an electronic organizer, an electronic book, a portable multimedia player (“PMP”), a navigation system, an ultra mobile PC (“UMPC”), or the like. The display device 20 in an embodiment may be applied as a display module 11 of electronic devices 10 such as a television, a laptop, a monitor, a billboard, or an Internet-of-Things (“IoT”) terminal, or the like. The display device 20 in an embodiment may be applied to electronic devices 10 such as a smart watch, a watch phone, a head mounted display (“HMD”) for implementing virtual reality and augmented reality, or the like.

The display device 20 in an embodiment may include a display panel 100, a heat dissipation layer 200, a circuit board 300, a timing control circuit (also referred to as a timing controller) 400, and a power supply circuit (also referred to as a power supply unit) 500.

The display panel 100 may have a planar shape similar to a quadrilateral shape. In an embodiment, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

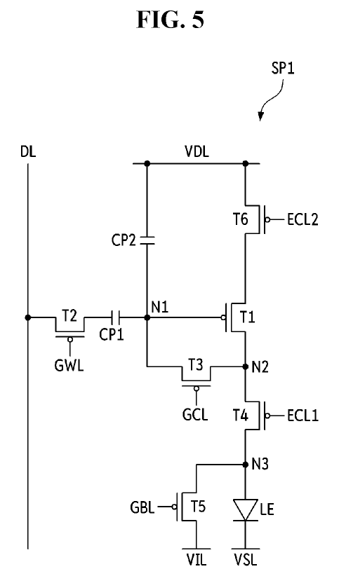

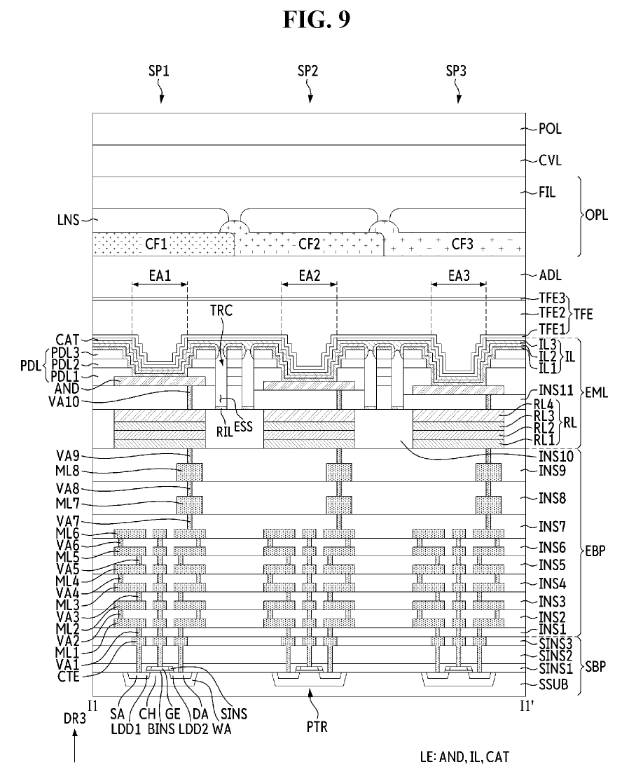

The plurality of pixels PX may include a plurality of sub-pixels SP1, SP2, and SP3. The plurality of sub-pixels SP1, SP2, and SP3 may include a plurality of pixel transistors as shown in FIG. 5, and the plurality of pixel transistors may be formed by a semiconductor process and disposed on a semiconductor substrate SSUB (refer to FIG. 9). In an embodiment, the plurality of pixel transistors of the data driver 700 may include or consist of complementary metal oxide semiconductor (“CMOS”), but the disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (refer to FIG. 9) through a semiconductor process. In an embodiment, the plurality of scan transistors and the plurality of light-emitting transistors may include or consist of CMOS, but the disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (refer to FIG. 9) through a semiconductor process. In an embodiment, the plurality of data transistors may include or consist of CMOS, but the disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, e.g., on the rear surface thereof. The heat dissipation layer 200 serves to dissipate heat generated from the display panel 100. The heat dissipation layer 200 may include a metal layer having relatively high thermal conductivity, such as graphite, silver (Ag), copper (Cu), or aluminum (Al).

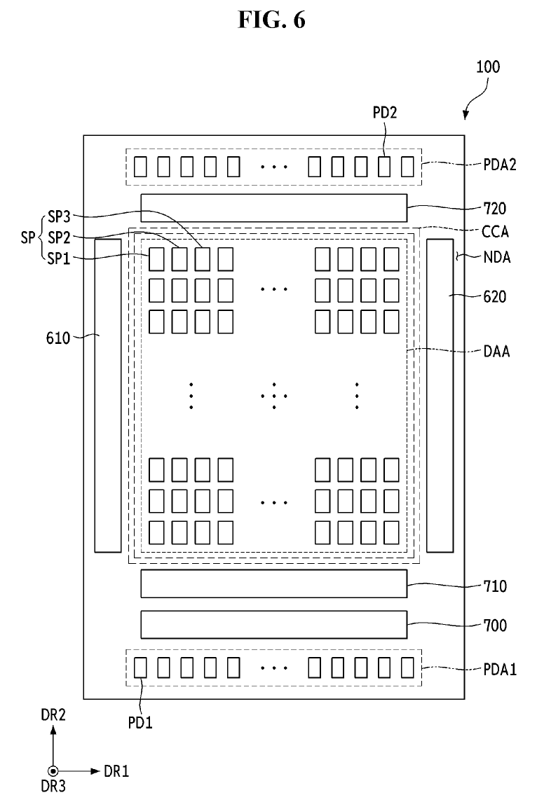

The circuit board 300 may be electrically connected to a plurality of first pads PD1 (refer to FIG. 6) of a first pad portion PDA1 (refer to FIG. 6) of the display panel 100 by a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. In this case, one end of the circuit board 300 may be disposed on the rear surface of the display panel 100 and/or the rear surface of the heat dissipation layer 200. An opposite end of the circuit board 300 may be connected to the plurality of first pads PD1 (refer to FIG. 6) of the first pad portion PDA1 (refer to FIG. 6) of the display panel 100 by a conductive adhesive member. One end of the circuit board 300 may be an opposite end of an opposite end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

Each of the timing control circuit 400 and the power supply circuit 500 may be formed as an integrated circuit (“IC”) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In an alternative embodiment, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (refer to FIG. 9) through a semiconductor process. In an embodiment, the plurality of timing transistors and the plurality of power transistors may include or consist of CMOS, but the disclosure is not limited thereto. Each of the timing control circuit 400 and the power supply circuit 500 may be disposed between the data driver 700 and the first pad portion PDA1 (refer to FIG. 6).

FIG. 5 is an equivalent circuit diagram illustrating an embodiment of a first sub-pixel shown in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a relatively low potential voltage is applied, a second driving voltage line VDL to which the second driving voltage VDD corresponding to a relatively high potential voltage is applied, and a third driving voltage line VIL to which the third driving voltage VINT corresponding to an initialization voltage is applied.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. In an embodiment, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as "driving current") flowing between the source electrode and the drain electrode thereof according to a voltage applied to the gate electrode thereof.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light-emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE.

The sixth transistor T6 may be disposed between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (“MOSFET”). In an embodiment, each of the first to sixth transistors T1 to T6 may be a P-type MOSFET, but the disclosure is not limited thereto. Each of the first to sixth transistors T1 to T6 may be an N-type MOSFET. In an alternative embodiment, some of the first to sixth transistors T1 to T6 may be P-type MOSFETs, and each of the remaining transistors may be an N-type MOSFET.

Although it is illustrated in FIG. 5 that the first sub-pixel SP1 includes six transistors T1 to T6 and two capacitors C1 and C2, it should be noted that the equivalent circuit diagram of the first sub-pixel SP1 is not limited to that shown in FIG. 5. In an embodiment, the number of transistors and the number of capacitors of the first sub-pixel SP1 are not limited to those shown in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, the description of the equivalent circuit diagram of the second sub-pixel SP2 and the equivalent circuit diagram of the third sub-pixel SP3 is not repeated in the disclosure.

FIG. 6 is a schematic plan view illustrating an embodiment of a display panel shown in FIG. 3.

Referring to FIG. 6, the display area DAA of the display panel 100 in an embodiment includes the plurality of pixels PX arranged in a matrix form. The non-display area NDA of the display panel 100 in an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. In an embodiment, the scan driver 610 may be disposed on one side of the display area DAA in the first direction DR1, and the emission driver 620 may be disposed on an opposite side of the display area DAA in the first direction DR1. However, the disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including or consisting of a rigid material or a flexible printed circuit board including or consisting of a flexible material.

The second pad portion PDA2 may be disposed on the fourth side of the display area DAA. In an embodiment, the second pad portion PDA2 may be disposed on an opposite side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. In an embodiment, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. In an embodiment, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may inspect the operation of each of the pixels PX in the display area DAA. The second distribution circuit 720 may be disposed on the fourth side of the display area DAA of the display panel 100. In an embodiment, the second distribution circuit 720 may be disposed on an opposite side of the display area DAA in the second direction DR2.

A cathode connection part CCA may be a region where a second electrode CAT (refer to FIG. 9) of a display element layer EML (refer to FIG. 9) is connected to the first driving voltage line VSL of the non-display area NDA. The cathode connection part CCA may be disposed outside at least one side of the display area DAA. In an embodiment, the cathode connection part CCA may be disposed outside at least on one side among the left side, the right side, the upper side, and the lower side of the display area DAA. In an alternative embodiment, the cathode connection part CCA may be disposed to surround the display area DAA as shown in FIG. 6 in order to minimize a deviation in the first driving voltage VSS caused by voltage drop (IR drop) or voltage rise (IR rising) of the second electrode CAT in the display area DAA.

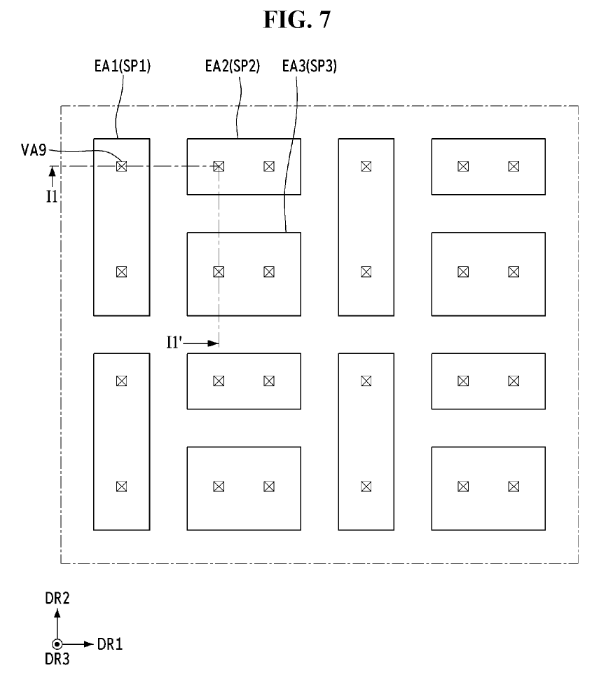

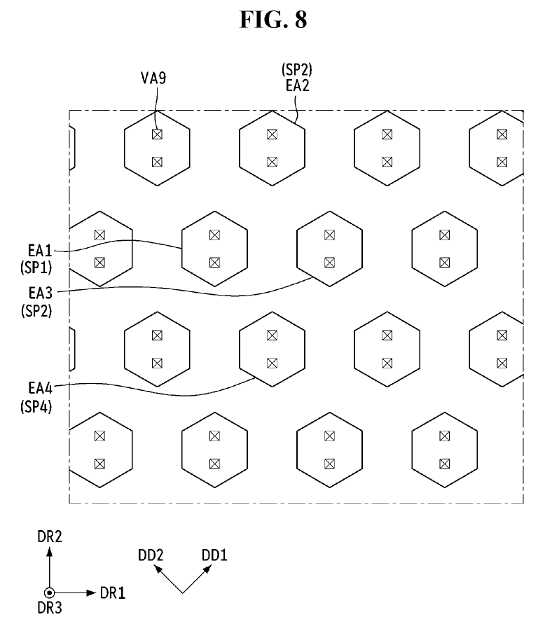

FIG. 7 is a schematic enlarged plan view illustrating an embodiment of a display area shown in FIG. 6. FIG. 8 is a schematic enlarged plan view illustrating another embodiment of the display area shown in FIG. 6.

Referring to FIGS. 7 and 8, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 7 and 8, but the disclosure is not limited thereto. The first emission area EA1, the second emission area EA2, and the third emission area EA3 may have a polygonal shape other than a quadrangle or hexagon, a circular shape, an elliptical shape, or an atypical shape in a plan view.

As shown in FIG. 7, in each of the plurality of pixels PX, the first emission area EA1 and the second emission area EA2 may be next (adjacent) to each other in the first direction DR1. Further, the first emission area EA1 and the third emission area EA3 may be next (adjacent) to each other in the first direction DR1. In addition, the second emission area EA2 and the third emission area EA3 may be next (adjacent) to each other in the second direction DR2. The area of the first emission area EA1, the area of the second emission area EA2, and the area of the third emission area EA3 may be different.

In an alternative embodiment, as shown in FIG. 8, the emission areas EA1, EA2, EA3, and EA4 may have a hexagonal shape in a plan view. In this case, the first emission area EA1 and the third emission area EA3 may be next (adjacent) in the first direction DR1, and the second emission area EA2 and the fourth emission area EA4 may be next (adjacent) in the second direction DR2. Additionally, the first emission area EA1 and the second emission area EA2 may be next (adjacent) to each other in a first diagonal direction DD1, and the second emission area EA2 and the third emission area EA3 may be next (adjacent) to each other in a second diagonal direction DD2. Additionally, the first emission area EA1 and the fourth emission area EA4 may be next (adjacent) to each other in the second diagonal direction DD2, and the third emission area EA3 and the fourth emission area EA4 may be next (adjacent) to each other in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. In an embodiment, the blue wavelength band may be a wavelength band of light whose main peak wavelength is in the range of approximately 370 nanometers (nm) to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

As shown in FIG. 7, each of the plurality of pixels PX may include three emission areas EA1, EA2, and EA3, or may include four emission areas EA1, EA2, EA3, and EA4 as shown in FIG. 8. In this case, the fourth emission area EA4 may emit the same second light as the second emission area EA2, but the disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as shown in FIG. 8, or a hexagonal structure in which the emission areas are arranged in a hexagonal shape.

FIG. 9 is a schematic cross-sectional view illustrating an embodiment of the display panel taken along line I1-I1' shown in FIG. 7.

Referring to FIG. 9, the display panel 100 includes a semiconductor backplane SBP, a light-emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an embodiment, when the first type impurity is a p-type impurity, the second type impurity may be an n-type impurity. In an alternative embodiment, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on an opposite side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include or consist of silicon carbonitride (SiCN) or a silicon oxide (SiOx)-based inorganic film, but the disclosure is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that may be bent or curved.

The light-emitting element backplane EBP includes a plurality of conductive layers ML1 to ML8, a plurality of vias VA1 to VA9, and a plurality of inter-insulating films INS1 to INS9.

The first to ninth inter-insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 5.

In an embodiment, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE is also accomplished through the first to eighth conductive layers ML1 to ML8.

The first to eighth conductive layers ML1 to ML8 and the first to eighth vias VA1 to VA8 may include or consist of substantially the same material as each other. The first to eighth conductive layers ML1 to ML8 and the first to eighth vias VA1 to VA8 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include or consist of substantially the same material as each other. First to eighth inter-insulating films INS1 to INS8 may include or consist of a silicon oxide (SiOx)-based inorganic layer, but the disclosure is not limited thereto.

A ninth inter-insulating film INS9 may be disposed on the eighth inter-insulating film INS8 and the eighth conductive layer ML8. The ninth inter-insulating film INS9 may include or consist of a silicon oxide (SiOx)-based inorganic film, but the disclosure is not limited thereto.

Each of the ninth vias VA9 may penetrate the ninth inter-insulating film INS9 and be connected to the exposed eighth conductive layer ML8. The ninth vias VA9 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light-emitting element backplane EBP. The display element layer EML may include the tenth and eleventh inter-insulating films INS10 and INS11, reflective electrodes RL, the first electrodes AND, a light-emitting stack IL, the second electrode CAT, a pixel defining film PDL, and a plurality of trenches TRC.

The reflective electrodes RL may be disposed on the ninth inter-insulating film INS9. Each of the reflective electrodes RL may include at least one reflective electrode RL1, RL2, RL3, and RL4. In an embodiment, each of the reflective electrodes RL may include the first to fourth reflective electrodes RL1, RL2, RL3, and RL4 as shown in FIG. 9.

The first reflective electrodes RL1 may be disposed on the ninth inter-insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the first reflective electrodes RL1 may include or consist of titanium nitride (TiN), the second reflective electrodes RL2 may include or consist of aluminum (Al), the third reflective electrodes RL3 may include or consist of titanium nitride (TiN), and the fourth reflective electrodes RL4 may include titanium (Ti).

The tenth inter-insulating film INS10 may be disposed on the ninth inter-insulating film INS9. The tenth inter-insulating film INS10 may be disposed between the reflective electrodes RL next (adjacent) to each other. The tenth inter-insulating film INS10 may be a film for flattening a stepped portion caused by the reflective electrodes RL. The eleventh inter-insulating film INS11 may be disposed on the tenth inter-insulating film INS10 and the reflective electrodes RL.

The tenth inter-insulating film INS10 and the eleventh inter-insulating film INS11 may include or consist of a silicon oxide (SiOx)-based inorganic film, but the disclosure is not limited thereto.

The eleventh inter-insulating film INS11 may be an optical auxiliary layer for adjusting the resonance distance of light emitted from the light-emitting stack IL in at least one of the first sub-pixel SP1, the second sub-pixel SP2, or the third sub-pixel SP3. The thickness of the eleventh inter-insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh inter-insulating film INS11 may be set for each of the first sub-pixel SP1, the second sub-pixel SP2, and the third sub-pixel SP3.

In an embodiment, as shown in FIG. 9, the thickness of the eleventh inter-insulating film INS11 in the first sub-pixel SP1 may be greater than the thickness of the eleventh inter-insulating film INS11 in the second sub-pixel SP2, and the thickness of the eleventh inter-insulating film INS11 in the second sub-pixel SP2 may be greater than the thickness of the eleventh inter-insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh inter-insulating film INS11 and be connected to the exposed fourth reflective electrode RL4. The tenth vias VA10 may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light-emitting elements LE may be disposed on the eleventh inter-insulating film INS11 and connected to the tenth via VA10. The first electrode AND of each of the light-emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light-emitting elements LE may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, the first electrode AND of each of the light-emitting elements LE may be titanium nitride (TiN).

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light-emitting element LE including the first electrode AND, the light-emitting stack IL, and the second electrode CAT is disposed.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may include or consist of a silicon oxide (SiOx)-based inorganic film. In an alternative embodiment, the first pixel defining film PDL1 and the third pixel defining film PDL3 may include or consist of a silicon nitride (SiNx)-based inorganic film, whereas the second pixel defining film PDL2 may include or consist of a silicon oxide (SiOx)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh inter-insulating film INS11 may be partially recessed at each of the plurality of trenches TRC.

At least one trench TRC may be disposed between the neighboring sub-pixels SP1, SP2, and SP3. Although FIG. 9 illustrates that two trenches TRC are disposed between the neighboring sub-pixels SP1, SP2, and SP3, the disclosure is not limited thereto.

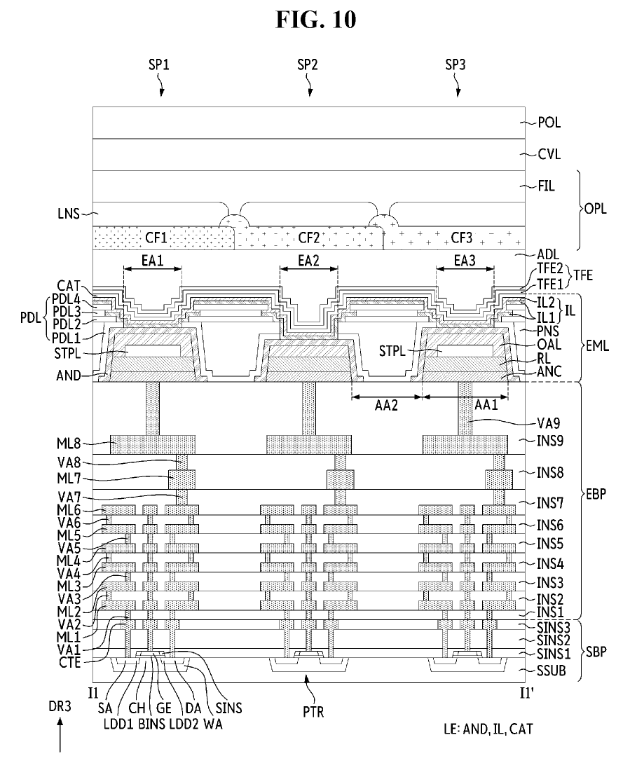

The light-emitting stack IL may include a plurality of stack layers IL1, IL2, and IL3. FIG. 9 illustrates that the light-emitting stack IL has a three-tandem structure including a first stack layer IL1, a second stack layer IL2, and a third stack layer IL3, but the disclosure is not limited thereto. In an embodiment, the light-emitting stack IL may have a two-tandem structure including two stack layers as shown in FIG. 10.

In the three-tandem structure, the light-emitting stack IL may have a tandem structure including a plurality of stack layers (also referred to as intermediate layers) IL1, IL2, and IL3 that emit different lights. In an embodiment, the light-emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light-emitting layer that emits the first light, and a first electron transport layer are sequentially stacked. The second stack layer IL2 may have a structure in which a second hole transport layer, a second light-emitting layer that emits the second light, and a second electron transport layer are sequentially stacked. The third stack layer IL3 may have a structure in which a third hole transport layer, a third light-emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as that of the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be defined between the residual film RIL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light-emitting stack IL of the display element layer EML between the neighboring sub-pixels SP1, SP2, and SP3, a different structure may be instead of the trench TRC. In an embodiment, instead of the trench TRC, a reverse tapered partition wall may be disposed on the pixel defining film PDL.

In addition, FIG. 9 illustrates that the light-emitting stack IL that emits light is disposed in the first emission area EA1, the second emission area EA2, and the third emission area EA3, but the disclosure is not limited thereto. In an embodiment, instead of the light-emitting stack IL, the first light-emitting layer may be disposed in the first emission area EA1, and may be omitted from the second emission area EA2 and the third emission area EA3. Furthermore, the second light-emitting layer may be disposed in the second emission area EA2 and may be omitted from the first emission area EA1 and the third emission area EA3. Furthermore, the third light-emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light-emitting stack IL. That is, the second electrode CAT may be disposed on the third stack layer IL3. The second electrode CAT may include or consist of a transparent conductive material (“TCO”) such as ITO or IZO that may transmit light or a semi-transmissive conductive material such as magnesium (Mg), silver (Ag), or an alloy of Mg and Ag. When the second electrode CAT includes or consists of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may include or consist of multiple layers in which one or more inorganic films of silicon nitride (SiNx), silicon oxynitride (SiON), silicon oxide (SiOx), titanium oxide (TiOx), and aluminum oxide (AlOx) layers are alternately stacked.

In addition, the encapsulation layer TFE may include at least one organic film TFE2 to protect the display element layer EML from foreign substances such as dust. The encapsulating organic film TFE2 may be disposed between the first encapsulating inorganic film TFE1 and the second encapsulating inorganic film TFE3. The encapsulation organic film TFE2 may be a monomer. In an alternative embodiment, the encapsulation organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 20. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. In an embodiment, the phase retardation film may be a λ/4 plate (quarter-wave plate), but the disclosure is not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another embodiment of the display panel taken along line I1-I1' shown in FIG. 7.

The embodiment of FIG. 10 differs from the embodiment of FIG. 9 in that the first electrode AND of each of the light-emitting elements LE contacts and electrically connected to the side surface of a connection electrode ANC connected to the eighth conductive layer ML8. The embodiment of FIG. 10 also differs from the embodiment of FIG. 9 in that the trench TRC is omitted, and instead, the third pixel defining film PDL3 and a fourth pixel defining film PDL4 have an eave-shaped or mushroom-shaped cross-sectional structure. In the embodiment of FIG. 10, redundant description of parts already described in the embodiment of FIG. 9 will be omitted.

Referring to FIG. 10, the plurality of connection electrodes ANC may be respectively disposed on first portions AA1 of the ninth inter-insulating film INS9. Each of the plurality of connection electrodes ANC may be disposed on the first portion AA1 of the ninth inter-insulating film INS9 corresponding thereto. A plurality of connection electrodes ANC may include or consist of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. In an embodiment, the plurality of connection electrodes ANC may include titanium (Ti), titanium nitride (TiN), indium tin oxide (“ITO”), or indium zinc oxide (“IZO”), but the disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may include or consist of any one of copper (Cu), aluminum (Al), tungsten (W), molybdenum (Mo), chromium (Cr), gold (Au), titanium (Ti), nickel (Ni), and neodymium (Nd), or an alloy including any one of them. In an embodiment, each of the plurality of reflective electrodes RL may include aluminum (Al) having relatively high reflectivity.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may include or consist of a silicon oxide (SiOx)-based inorganic film, but the disclosure is not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, only the optical auxiliary film OAL may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light-emitting stack IL, and the wavelength and resonance distance of light emitted from the second stack layer IL2 thereof.

Each of the light-emitting elements LE may include the first electrode AND, a light-emitting stack IL, and a second electrode CAT.

The first electrode AND of each of the light-emitting elements LE may be disposed on the optical auxiliary film OAL corresponding thereto. Since the connection electrode ANC, the reflective electrode RL, and the optical auxiliary film OAL are sequentially stacked, the first electrode AND of each of the light-emitting elements LE may be disposed on the top surface and the side surface of the optical auxiliary film OAL, the side surface of the reflective electrode RL, and the side surface of the connection electrode ANC. Accordingly, the first electrode AND of each of the light-emitting elements LE may contact and electrically connected to the side surface of the reflective electrode RL and the side surface of the connection electrode ANC. Therefore, compared to when the first electrode AND of each of the light-emitting elements LE is connected to the reflective electrode RL exposed through a through hole penetrating the optical auxiliary film OAL, the number of mask processes may be reduced, thereby lowering manufacturing cost and increasing manufacturing efficiency.

The first electrode AND of each of the light-emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth inter-insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth inter-insulating film INS9 may be substantially the same.

In an alternative embodiment, the thickness of the first portion AA1 of the ninth inter-insulating film INS9 may be greater than the thickness of the second portion AA2 thereof. In this case, the side surface of the first portion AA1 of the ninth inter-insulating film INS9 may be exposed, and the first electrode AND of each of the light-emitting elements LE may be disposed on the exposed side surface of the first portion AA1 of the ninth inter-insulating film INS9.

The first electrode AND of each of the light-emitting elements LE may include or consist of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. In an embodiment, the first electrode AND of each of the light-emitting elements LE may include titanium (Ti), titanium nitride (TiN), indium tin oxide (“ITO”), or indium zinc oxide (“IZO”), but the disclosure is limited thereto.

The pixel defining film PDL may be disposed on a part of the first electrode AND of each of the light-emitting elements LE. The pixel defining film PDL may cover the edge of the first electrode AND of each of the light-emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light-emitting elements LE. Specifically, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth inter-insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth inter-insulating film INS9.

The planarization film PNS may be disposed between the connection electrodes ANC next (adjacent) to each other in the first direction DR1 or the second direction DR2. The planarization film PNS may be disposed between the reflective electrodes RL next (adjacent) to each other in the first direction DR1 or the second direction DR2. The planarization film PNS may be disposed between the optical auxiliary films OAL next (adjacent) to each other in the first direction DR1 or the second direction DR2.

The step layer STPL is not in the second emission area EA2, whereas the step layer STPL is in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In contrast, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may include or consist of a silicon nitride (SiNx)-based inorganic film, whereas the second pixel defining film PDL2, the fourth pixel defining film PDL4, and the planarization film PNS may include or consist of a silicon oxide (SiOx)-based inorganic film. The first pixel defining film PDL1 includes or consists of a material different from that of the planarization film PNS, and thus may serve as a stopper in a chemical mechanical polishing process for the planarization film PNS.

When the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. That is, the third pixel defining film PDL3 and the fourth pixel defining film PDL4 may have an eaves-shaped or mushroom-shaped cross-sectional structure.

The light-emitting stack IL may be disposed on the first electrode AND and the pixel defining film PDL. The light-emitting stack IL may include the first stack layer IL1 and the second stack layer IL2 that emit different lights. When the light-emitting stack IL has a two-tandem structure, one of the first stack layer IL1 and the second stack layer IL2 may emit light that includes the wavelength range of any one of the first light, the second light, and the third light, and a remaining (the other) one may emit light that includes the wavelength ranges of remaining (the other) two lights. In an embodiment, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the emission areas EA1, EA2, and EA3 next (adjacent) to each other. Accordingly, it is possible to prevent the light-emitting stack IL in the emission areas EA1, EA2, and EA3 next (adjacent) to each other from emitting light other than the originally intended light due to the influence of the above current.

Although FIG. 10 illustrates a two-tandem structure in which the light-emitting stack IL includes two stack layers IL1 and IL2, the disclosure is not limited thereto. In an embodiment, the light-emitting stack IL may have a three-tandem structure including three stack layers as shown in FIG. 9. In this case, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. In an alternative embodiment, as shown in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth inter-insulating film INS9, but the disclosure is not limited thereto.

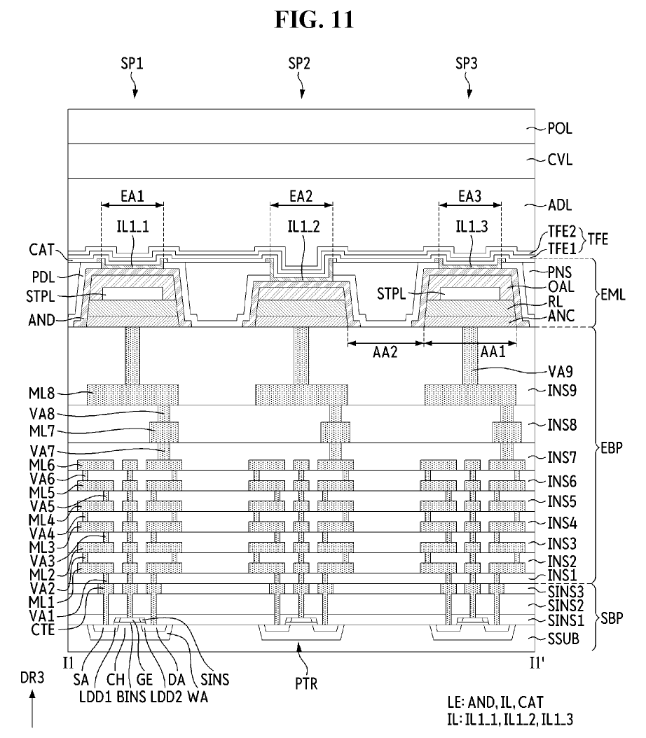

FIG. 11 is a schematic cross-sectional view illustrating another embodiment of the display panel taken along line I1-I1' shown in FIG. 7.

The embodiment of FIG. 11 differs from the embodiment of FIG. 10 in that the light-emitting elements LE have a single stack structure. In the embodiment of FIG. 11, redundant description of parts already described in the embodiment of FIG. 10 will be omitted.

Referring to FIG. 11, the pixel defining film PDL may be disposed on the ninth inter-insulating film INS9 and the first electrodes AND, and the planarization film PNS may be disposed on the pixel defining film PDL. The planarization film PNS and the pixel defining film PDL may define openings exposing the first electrodes AND, and light-emitting stack IL may be disposed on the first electrodes AND. In an embodiment, the pixel defining film PDL may define openings exposing the first electrodes AND in the first light emission area EA1, the second light emission area EA2 and the third light emission area EA3, and the planarization film PNS may define an opening exposing the first electrode AND in the second light emission area EA2. In an embodiment, the light-emitting stack IL may include a first stack layer IL1_1, a second stack layer IL1_2, and a third stack layer IL1_3.

The first stack layer IL1_1 may be disposed on the first electrode AND exposed by the pixel defining film PDL in the first light emission area EA1. The first stack layer IL1_1 may also be disposed on a portion of the pixel defining film PDL. In an embodiment, the first stack layer IL1_1 may include a hole injecting layer, a hole transporting layer, a first light-emitting layer, an electron transporting layer, and an electron injecting layer.

The second stack layer IL1_2 may be disposed on the first electrode AND exposed by the planarization film PNS and the pixel defining film PDL in the second light emission area EA2. The second stack layer IL1_2 may also be disposed on a portion of the planarization film PNS. In an embodiment, the second stack layer IL1_2 may include the hole injecting layer, the hole transporting layer, a second light-emitting layer, the electron transporting layer, and the electron injecting layer.

The third stack layer IL1_3 may be disposed on the first electrode AND exposed by the pixel defining film PDL in the third light emission area EA3. The third stack layer IL1_3 may also be disposed on a portion of the pixel defining film PDL. In an embodiment, the third stack layer IL1_3 may include the hole injecting layer, the hole transporting layer, a third light-emitting layer, the electron transporting layer, and the electron injecting layer.

The first stack layer IL1_1, the second stack layer IL1_2, and the third stack layer IL1_3 may be spaced apart from each other, and thus the second to fourth pixel defining films PDL2, PDL3 and PDL4 used to separate the light-emitting stack IL in the embodiment of FIG. 10 may be omitted.

The first stack IL1_1 of the first light emission area EA1 may emit first light, the second stack layer IL1_2 of the second light emission area EA2 may emit second light, and the third stack layer IL1_3 of the third light emission area EA3 may emit third light. Accordingly, the first to third color filters CF1, CF2 and CF3 of the optical layer OPL used in the embodiment of FIG. 9, the plurality of lenses LNS, and the filling layer FIL may be omitted.

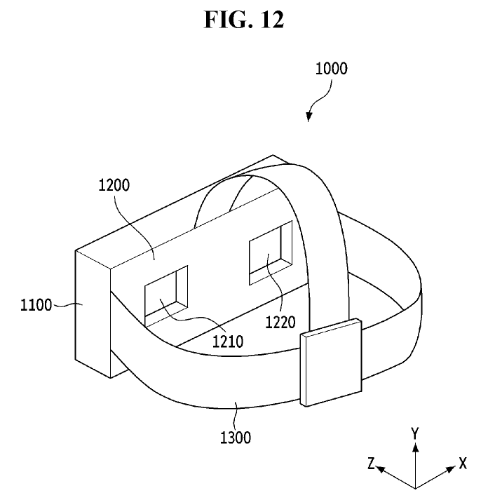

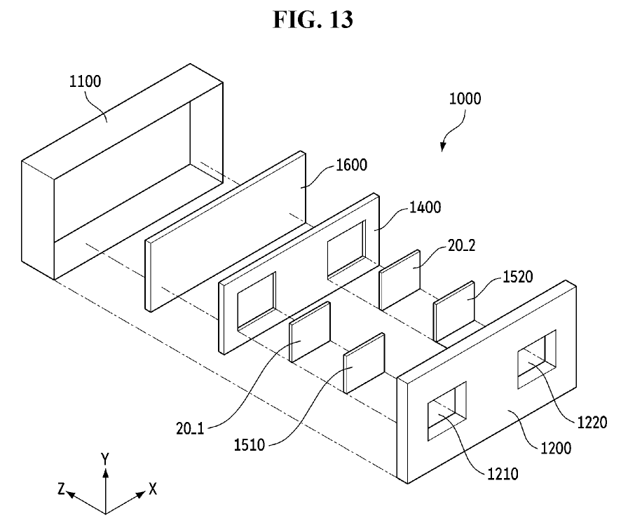

FIG. 12 is a schematic perspective view illustrating one embodiment of a head mounted display. FIG. 13 is a schematic exploded perspective view illustrating the head mounted display shown in FIG. 12.

Referring to FIGS. 12 and 13, a head mounted display 1000 in an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 11, the description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data DATA, and transmit the digital video data DATA to the first display device 20_1 and the second display device 20_2 through the connector.

The control circuit board 1600 may transmit the digital video data DATA corresponding to a left-eye image optimized for the user's left eye to the first display device 20_1, and may transmit the digital video data DATA corresponding to a right-eye image optimized for the user's right eye to the second display device 20_2. In an alternative embodiment, the control circuit board 1600 may transmit the same digital video data DATA to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 12 and 13 illustrate that the first eyepiece 1210 and the second eyepiece 1220 are disposed separately, but the disclosure is not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

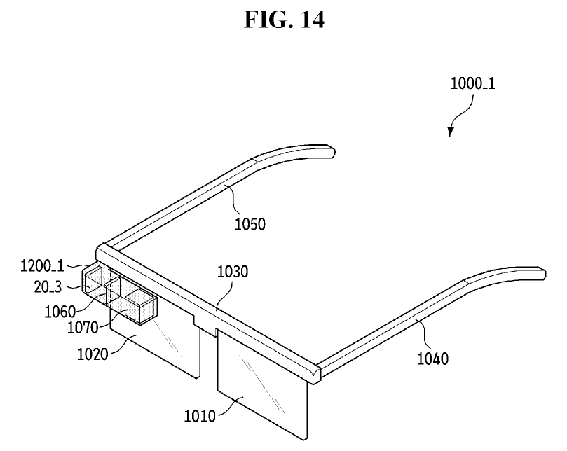

The head mounted band 1300 serves to secure the display device housing 1100 to the user's head such that the first eyepiece 1210 and the second eyepiece 1220 of the housing cover 1200 remain disposed on the user's left and right eyes, respectively. When the housing cover 1200 is implemented to be lightweight and compact, the head mounted display 1000 may be provided with, as shown in FIG. 14, an eyeglass frame instead of the head mounted band 1300.

FIG. 14 is a schematic perspective view illustrating another embodiment of a head mounted display.

Referring to FIG. 14, a head mounted display 1000_1 in an embodiment may be an eyeglasses-type display device in which a display device housing 1200_1 is implemented in a lightweight and compact manner. The head mounted display 1000_1 in an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 14 illustrates that the display device housing 1200_1 is disposed at the right end of the support frame 1030, but the disclosure is not limited thereto. In an embodiment, the display device housing 1200_1 may be disposed at the left end of the support frame 1030, and in this case, the image of the display device 20_3 may be provided to the user's left eye. In an alternative embodiment, the display device housing 1200_1 may be disposed at both the left and right ends of the support frame 1030, and in this case, the user may view the image displayed on the display device 20_3 through both the left and right eyes.

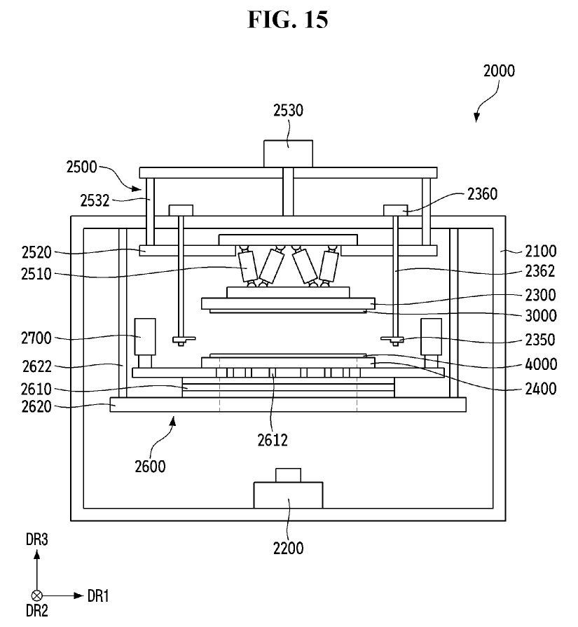

FIG. 15 is a schematic diagram illustrating an embodiment of a deposition mask and a deposition apparatus including the deposition mask.

Referring to FIG. 15, a deposition apparatus 2000 in an embodiment may be used to form a deposition material layer on a substrate. In an embodiment, the deposition apparatus 2000 in an embodiment may be used to form light-emitting layers on a backplane substrate 3000 (or display substrate) in a manufacturing process of the display panel 100 (refer to FIG. 3). In an embodiment, as shown in FIG. 11, the semiconductor backplane SBP and the light-emitting element backplane EBP may be disposed on the backplane substrate 3000, and electrode patterns, e.g., the first electrodes AND functioning as anode electrodes, may be disposed on the light-emitting element backplane EBP. In addition, the pixel defining film PDL in which openings that expose the first electrodes AND are defined may be disposed on the light-emitting element backplane EBP. In an embodiment, the deposition apparatus 2000 may form first light-emitting layers on the first electrodes AND of the first emission areas EA1. In another embodiment, the deposition apparatus 2000 may form second light-emitting layers on the first electrodes AND of the second emission areas EA2. In another embodiment, the deposition apparatus 2000 may form third light-emitting layers on the first electrodes AND of the third emission areas EA3.

The deposition apparatus 2000 may include a deposition source 2200 for providing a vapor deposition material on the backplane substrate 3000, a substrate chuck 2300 for supporting the backplane substrate 3000 to face the deposition source 2200, and a mask chuck 2400 disposed between the deposition source 2200 and the substrate chuck 2300 to support a deposition mask 4000 to face the backplane substrate 3000. The deposition source 2200, the substrate chuck 2300, and the mask chuck 2400 may be disposed in a process chamber (or an evaporation chamber) 2100.

A process chamber 2100 may have an internal space, and a deposition process for forming a deposition material layer on the backplane substrate 3000 may be performed in the internal space of the process chamber 2100. The process chamber 2100 may be connected to a vacuum pump (not shown), and a vacuum atmosphere may be created in the internal space of the process chamber 2100 by the vacuum pump. An opening (not shown) for loading/unloading of the backplane substrate 3000 and the deposition mask 4000 may be defined in one wall of the process chamber 2100, and the opening may be opened and closed by a gate valve (not shown).

The deposition source 2200 may be disposed in the process chamber 2100, and a deposition material may be stored in the deposition source 2200. The deposition source 2200 may evaporate a deposition material such as an organic material, an inorganic material, a conductive material, or the like toward the backplane substrate 3000, and the evaporated deposition material may be deposited on the backplane substrate 3000 through the deposition mask 4000. In an embodiment, the deposition source 2200 may evaporate an organic light-emitting material for forming light-emitting layers on the backplane substrate 3000, and may be provided with a heater (not shown) for evaporating the organic light-emitting material. The evaporated organic light-emitting material may be deposited on electrode patterns on the backplane substrate 3000 through the deposition mask 4000, thereby forming light-emitting layers on the electrode patterns of the backplane substrate 3000. As shown in FIG. 15, the deposition source 2200 may be disposed on the central portion of the bottom surface of the process chamber 2100, but the deposition source 2200 may move horizontally by a separate driver (not shown).

The substrate chuck 2300 may be disposed above the deposition source 2200 and may support the backplane substrate 3000 such that the backplane substrate 3000 faces the deposition source 2200. In an embodiment, the substrate chuck 2300 may be an electrostatic chuck that holds the rear surface of the backplane substrate 3000 using an electrostatic force. Specifically, the electrode patterns, e.g., first electrodes AND, may be disposed on the front surface of the backplane substrate 3000, and the substrate chuck 2300 may hold the rear surface of the backplane substrate 3000 such that the front surface of the backplane substrate 3000 faces downward, that is, faces the deposition source 2200.

A plurality of lift fingers 2350 for loading the backplane substrate 3000 onto the substrate chuck 2300 may be arranged in the process chamber 2100. The lift fingers 2350 may be arranged around the substrate chuck 2300 and the mask chuck 2400, and may be respectively moved vertically by finger drivers 2360. In an embodiment, three or four lift fingers 2350 may be arranged around the substrate chuck 2300 and the mask chuck 2400, and may be moved in the third direction DR3 by the finger drivers 2350.

The backplane substrate 3000 may be loaded into the process chamber 2100 by a transfer robot (not shown), and may be transferred from the transfer robot onto the lift fingers 2350 under the substrate chuck 2300. In this case, the rear surface of the backplane substrate 3000 may face the bottom surface of the substrate chuck 2300, and the lift fingers 2350 may support the front edge portions of the backplane substrate 3000. The finger drivers 2360 may raise the lift fingers 2350 such that the backplane substrate 3000 becomes next (adjacent) to the bottom surface of the substrate chuck 2300, and the rear surface of the backplane substrate 3000 may be held on the bottom surface of the substrate chuck 2300 by an electrostatic force.

The finger drivers 2360 may be arranged on the upper lid of the process chamber 2100 and may be respectively connected to the lift fingers 2350 through driving shafts 2362 that extend vertically through the upper lid of the process chamber 2100. The finger drivers 2360 may vertically move the lift fingers 2350 to load or unload the backplane substrate 3000. In addition, the finger drivers 2360 may rotate the lift fingers 2350 with respect to each of the driving shafts 2362. In an embodiment, the finger drivers 2360 may rotate the lift fingers 2350 such that the ends of the lift fingers 2350 do not overlap the substrate chuck 2300 and the mask chuck 2400, thereby enabling vertical movement of the lift fingers 2350. In addition, the finger drivers 2360 may rotate the lift fingers 2350 such that the ends of the lift fingers 2350 overlap the edge portions of the backplane substrate 3000 to support the edge portions of the backplane substrate 3000.

The deposition mask 4000 may be loaded into the process chamber 2100 by the transfer robot, and may be transferred onto the lift fingers 2350 above the mask chuck 2400. The edge portions of the deposition mask 4000 may be placed on the ends of the lift fingers 2350, and the finger drivers 2360 may lower the lift fingers 2350 to load the deposition mask 4000 onto the mask chuck 2400. In this case, recesses (not shown) into which ends of lift fingers 2350 are inserted may be provided at the edge portions of the mask chuck 2400, and the finger drivers 2360 may rotate the lift fingers 2350 such that the lift fingers 2350 do not overlap the mask chuck 2400 after the deposition mask 4000 is loaded on the mask chuck 2400.

The mask chuck 2400 may support the edge portion of the deposition mask 4000. In an embodiment, the mask chuck 2400 may be an electrostatic chuck configured to hold the edge portion of the deposition mask 4000 using an electrostatic force. In particular, a circular opening to expose the deposition mask 4000 toward the deposition source 2200 may be defined in the mask chuck 2400. In an embodiment, the mask chuck 2400 may have a disk shape or a quadrilateral plate shape with a circular opening.

The deposition apparatus 2000 may include a chuck driver for adjusting the position and posture of the backplane substrate 3000 and the deposition mask 4000. In an embodiment, the deposition apparatus 2000 may include a substrate chuck driver 2500 for moving the substrate chuck 2300 and a mask chuck driver 2600 for moving the mask chuck 2400.

The substrate chuck driver 2500 may move the substrate chuck 2300 in the first direction DR1, the second direction DR2, and the third direction DR3 to adjust the position of the backplane substrate 3000. In this case, the first direction DR1 may be the first horizontal direction, the second direction DR2 may be the second horizontal direction perpendicular to the first direction DR1, and the third direction DR3 may be the vertical direction. In an embodiment, the first direction DR1, the second direction DR2, and the third direction DR3 may be an X-axis direction, a Y-axis direction, and a Z-axis direction, respectively.

The substrate chuck driver 2500 may rotate the substrate chuck 2300 around the Z-axis to adjust the azimuth of the backplane substrate 3000, that is, the angle at which the backplane substrate 3000 is held on the bottom surface of the substrate chuck 2300. Further, the substrate chuck driver 2500 may rotate the substrate chuck 2300 around the X-axis, and may also rotate the substrate chuck 2300 around the Y-axis in order to adjust the inclination of the backplane substrate 3000. In an embodiment, the substrate chuck driver 2500 may include a hexapod actuator 2510 that provides a motion of six degrees of freedom (X, Y, Z, θx, θy, and θz).

The substrate chuck driver 2500 may include a substrate stage 2520 to which the hexapod actuator 2510 is disposed (e.g., mounted), and a second actuator 2530 connected to the substrate stage 2520. The substrate stage 2520 may be disposed horizontally in the process chamber 2100, and the second actuator 2530 may be disposed above the process chamber 2100. The second actuator 2530 may be connected to the substrate stage 2520 by a plurality of driving shafts 2532 extending in the third direction DR3, i.e., the vertical direction (Z-axis direction) through the upper lid of the process chamber 2100, and may move the substrate stage 2520 in the central axis direction of the hexapod actuator 2510, i.e., the vertical direction. In an embodiment, the second actuator 2530 may be configured using a brushless DC motor, a linear motor, a direct drive (DD) motor, or the like, and may adjust the height of the substrate chuck 2300 for loading or unloading the backplane substrate 3000.

The hexapod actuator 2510 may include a first platform connected to the substrate chuck 2300, a second platform disposed (e.g., mounted) to the substrate stage 2520, and six sub-actuators disposed between the first platform and the second platform. In an embodiment, the six sub-actuators may each be configured using a brushless DC motor, a voice coil linear motor, a step motor, a direct drive (DD) motor, a servo motor, or the like, and may move and rotate the first platform to adjust the horizontal position, vertical position, azimuth, and inclination of the backplane substrate 3000.

The mask chuck driver 2600 may move and rotate the mask chuck 2400 to adjust the horizontal position of the deposition mask 4000 and the azimuth angle of the deposition mask 4000, that is, the angle at which the deposition mask 4000 is placed on the mask chuck 2400. The mask chuck driver 2600 may move the mask chuck 2400 in a direction parallel to the deposition mask 4000 and rotate the mask chuck 2400 with respect to the central axis of the mask chuck 2400. In an embodiment, the mask chuck driver 2600 may move the mask chuck 2400 in the first direction DR1 (X-axis) and the second direction DR2 (Y-axis), and may rotate the mask chuck 2400 with respect to the third direction DR3 (Z-axis).

The mask chuck driver 2600 may include a piezo actuator 2610 that provides a motion of three degrees of freedom (X, Y, and θz), for example. The piezo actuator 2610 may define an opening communicating with the circular opening of the mask chuck 2400. The mask chuck 2400 may be spaced upward from the piezo actuator 2610 by a selected distance. In an embodiment, a plurality of support members 2612 may be arranged on the piezo actuator 2610, and the mask chuck 2400 may be disposed on the plurality of support members 2612.

The mask chuck driver 2600 may include a mask stage 2620 that is horizontally disposed in the process chamber 2100 and supports the piezo actuator 2610. In an embodiment, the mask stage 2620 may define an opening that communicates with the opening of the piezo actuator 2610 and may be supported by a plurality of posts 2622 that are connected to the upper lid of the process chamber 2100.

After the backplane substrate 3000 and the deposition mask 4000 are loaded onto the substrate chuck 2300 and the mask chuck 2400, respectively, the second actuator 2530 may lower the substrate chuck 2300 such that the backplane substrate 3000 is brought next (adjacent) to the deposition mask 4000. The hexapod actuator 2510 may adjust the gap between the backplane substrate 3000 and the deposition mask 4000, and may adjust the inclination of the substrate chuck 2300 to adjust the parallelism between the substrate chuck 2300 and the mask chuck 2400. In an embodiment, although not shown, a plurality of gap sensors (not shown) for measuring the gap between the substrate chuck 2300 and the mask chuck 2400 may be disposed (e.g., mounted) at the substrate chuck 2300, and the hexapod actuator 2510 may adjust the parallelism between the substrate chuck 2300 and the mask chuck 2400 based on the measured values of the gap sensors.

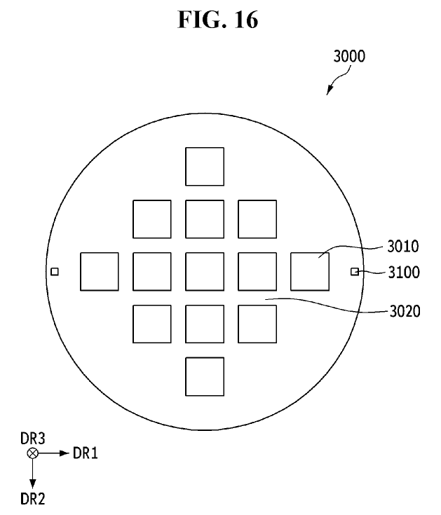

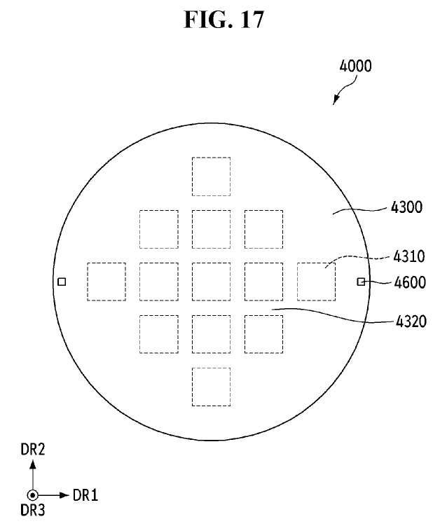

The deposition apparatus 2000 may include cameras 2700 for acquiring positional information of the backplane substrate 3000 and the deposition mask 4000 for alignment between the backplane substrate 3000 and the deposition mask 4000. In an embodiment, substrate alignment keys 3100 (refer to FIG. 16) may be arranged on the edge portions of the backplane substrate 3000, and mask alignment keys 4600 (refer to FIG. 17) may be arranged on the edge portions of the deposition mask 4000. The deposition apparatus 2000 may include the cameras 2700 for detecting the substrate alignment keys 3100 and the mask alignment keys 4600, and the substrate chuck driver 2500 or the mask chuck driver 2600 may align the backplane substrate 3000 and the deposition mask 4000 with each other based on the positional information of the substrate alignment keys 3100 and the mask alignment keys 4600 obtained by the cameras 2700.

As described above, after the parallelism adjustment between the substrate chuck 2300 and the mask chuck 2400 and the positional alignment between the backplane substrate 3000 and the deposition mask 4000 are performed, the backplane substrate 3000 may be disposed on the deposition mask 4000. In an embodiment, the hexapod actuator 2510 may adjust the height of the substrate chuck 2300 such that the gap between the backplane substrate 3000 and the deposition mask 4000 becomes a selected gap, e.g., a gap of several μm. In another embodiment, the hexapod actuator 2510 may adjust the height of the substrate chuck 2300 such that the backplane substrate 3000 is brought into contact with the deposition mask 4000.

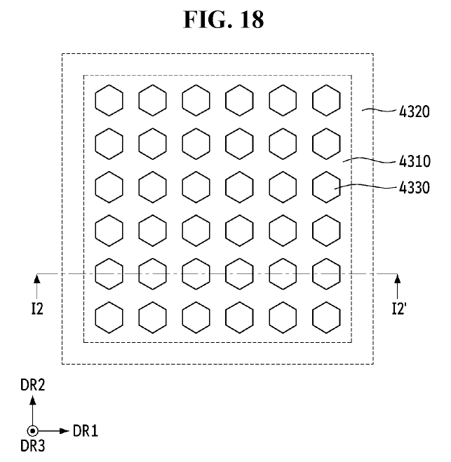

After the backplane substrate 3000 is disposed on the deposition mask 4000, the deposition source 2200 may provide a vapor deposition material onto the backplane substrate 3000 through the deposition mask 4000, thereby forming a deposition material layer on the backplane substrate 3000. In an embodiment, the deposition source 2200 may provide a vapor light-emitting material for forming light-emitting layers on the backplane substrate 3000, and the vapor light-emitting material may be deposited on the electrode patterns of the backplane substrate 3000 through pixel openings 4212 (refer to FIG. 18) of the deposition mask 4000.

FIG. 16 is a schematic bottom view illustrating the backplane substrate shown in FIG. 15.

Referring to FIG. 16, the backplane substrate 3000 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 16, and may be individualized into the display panels 100 (refer to FIG. 3) by a dicing process after the display manufacturing process is completed. In an embodiment, the first direction DR1 may be a first horizontal direction, and the second direction DR2 may be a second horizontal direction perpendicular to the first direction DR1. In addition, each of the display cell regions 3010 may have a quadrilateral shape as shown in the drawing, for example.

In an embodiment, each of the display cell regions 3010 may include the semiconductor backplane SBP and the light-emitting element backplane EBP disposed on the semiconductor backplane SBP, as shown in FIG. 11. In addition, a plurality of electrode patterns, e.g., the plurality of first electrodes AND may be disposed on the light-emitting element backplane EBP, and the pixel defining film PDL defining openings that expose the first electrodes AND may be disposed on the light-emitting element backplane EBP and the first electrodes AND. In this case, the electrode patterns of the display cell regions 3010 may be arranged on the front surface of the backplane substrate 3000, and the substrate chuck 2300 may hold the rear surface of the backplane substrate 3000 such that the electrode patterns of the display cell regions 3010 face downward, i.e., face the deposition source 2200.

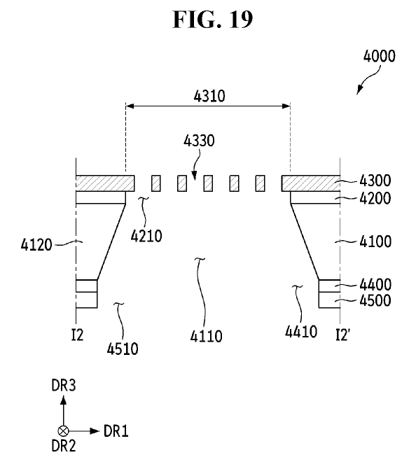

FIG. 17 is a schematic plan view illustrating the deposition mask shown in FIG. 15. FIG. 18 is a schematic plan view illustrating the mask cell region shown in FIG. 17. FIG. 19 is a schematic cross-sectional view taken along line I2-I2' shown in FIG. 18.

Referring to FIGS. 17 to 19, the deposition mask 4000 may include mask cell regions 4310 respectively corresponding to the display cell regions 3010 of the backplane substrate 3000, and a grid region 4320 corresponding to the scribe lane region 3020 of the backplane substrate 3000. Each of the mask cell regions 4310 may define a plurality of pixel openings 4330 exposing the first electrodes AND of the backplane substrate 3000 in a deposition process. In an embodiment, when the backplane substrate 3000 is disposed on the deposition mask 4000 in the deposition process, the electrode patterns, e.g., the first electrodes AND, of the backplane substrate 3000 may be disposed on the pixel openings 4330 of the deposition mask 4000, and accordingly, the first electrodes AND may be exposed toward the deposition source 2200 through the pixel openings 4330.

In an embodiment, the deposition mask 4000 may include a mask substrate 4100, a buffer inorganic film 4200 disposed on the mask substrate 4100, and a membrane 4300 disposed on the buffer inorganic film 4200. In this case, the membrane 4300 may include the plurality of mask cell regions 4310 and the grid region 4320 surrounding the mask cell regions 4310, and each of the mask cell regions 4310 may have the plurality of pixel openings 4330.

The mask substrate 4100 may define cell openings 4110 respectively corresponding to the mask cell regions 4310, and may include a rib region 4120 defining the cell openings 4110. The buffer inorganic film 4200 may define buffer openings 4210 respectively arranged on the cell openings 4110. In this case, the mask cell regions 4310 of the membrane 4300 may be respectively arranged on the buffer openings 4210, and the pixel openings 4330 of the membrane 4300 may communicate with the cell openings 4110 through the buffer openings 4210. That is, the buffer openings 4210 may be defined between the cell openings 4110 and the mask cell regions 4310. In an embodiment, the mask cell regions 4310 may be regions exposed through the cell openings 4110 and the buffer openings 4210.

In an embodiment, the mask cell regions 4310 of the membrane 4300 may be exposed toward the deposition source 2200 through the cell openings 4110 of the mask substrate 4100 and the buffer openings 4210 of the buffer inorganic film 4200, and the pixel openings 4330 may be defined to penetrate the mask cell regions 4310. In this case, while performing the deposition process, the vapor deposition material provided from the deposition source 2200 may be deposited on the first electrodes AND of the backplane substrate 3000 through the cell openings 4110, the buffer openings 4210, and the pixel openings 4330.

As shown in FIG. 17, the mask cell regions 4310 may be arranged in a matrix form along the first direction DR1 and the second direction DR2. In an embodiment, the first direction DR1 may be the first horizontal direction, and the second direction DR2 may be the second horizontal direction perpendicular to the first direction DR1. The mask cell regions 4310 may have a quadrilateral shape as shown in the drawing, and the pixel openings 4330 may be arranged to correspond to the first electrodes AND of any one of the first emission areas EA1, the second emission areas EA2, and the third emission areas EA3.

The mask substrate 4100 may include single crystal silicon, for example. In an embodiment, a single crystal silicon substrate having a thickness in the range of about 700 μm to about 800 μm, e.g., about 725 μm or about 775 μm, may be used as the mask substrate 4100.

The buffer inorganic film 4200 and the membrane 4300 may be disposed on the front surface of the mask substrate 4100, and an intermediate inorganic film 4400 and a rear inorganic film 4500 may be disposed on the rear surface of the mask substrate 4100. In an embodiment, the intermediate inorganic film 4400 may be disposed on the rear surface of the mask substrate 4100, and the rear inorganic film 4500 may be disposed on the intermediate inorganic film 4400.

The intermediate inorganic film 4400 and the rear inorganic film 4500 may define intermediate openings 4410 and rear openings 4510 communicating with the cell openings 4110, respectively, and the intermediate inorganic film 4400 and the rear inorganic film 4500 may function as an etching mask in an etching process for defining the cell openings 4110. In this case, the mask cell regions 4310 may be exposed toward the deposition source 2200 through the buffer openings 4210, the cell openings 4110, the intermediate openings 4410, and the rear openings 4510. In addition, the vapor deposition material provided from the deposition source 2200 during the deposition process may be deposited on the first electrodes AND of the backplane substrate 3000 through the rear openings 4510, the intermediate openings 4410, the cell openings 4110, the buffer openings 4210, and the pixel openings 4330.

In an embodiment, the membrane 4300 may include a material having etching selectivity with respect to the buffer inorganic film 4200 and the mask substrate 4100. In an embodiment, the buffer inorganic film 4200 may include silicon oxide (SiOx), and the membrane 4300 may include silicon nitride (SiNx). In an embodiment, the buffer inorganic film 4200 may include the same material as that of the intermediate inorganic film 4400, and the membrane 4300 may include the same material as that of the rear inorganic film 4500. In an embodiment, the buffer inorganic film 4200 and the intermediate inorganic film 4400 may be simultaneously formed to have a thickness of about 0.2 μm to about 2 μm through a thermal oxidation process, and the membrane 4300 and the rear inorganic film 4500 may be simultaneously formed to have a thickness of about 0.3 μm to about 3 μm through a chemical vapor deposition (“CVD”) process.

In another embodiment, the intermediate inorganic film 4400 may be omitted. In this case, the rear inorganic film 4500 may be disposed on the rear surface of the mask substrate 4100. In addition, the buffer inorganic film 4200 may be formed alone on the front surface of the mask substrate 4100 through a thermal oxidation process or a CVD process, and the rear inorganic film 4500 may be formed simultaneously with the membrane 4300 or may be formed separately from the membrane 4300. In another embodiment, both the buffer inorganic film 4200 and the intermediate inorganic film 4400 may be omitted. In this case, the membrane 4300 may be disposed on the front surface of the mask substrate 4100, and the rear inorganic film 4500 may be disposed on the rear surface of the mask substrate 4100. Additionally, the rear inorganic film 4500 may be formed simultaneously with the membrane 4300 or may be formed separately from the membrane 4300.

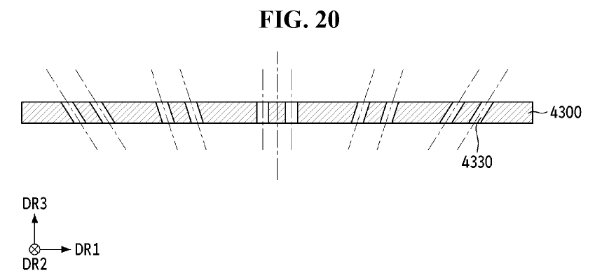

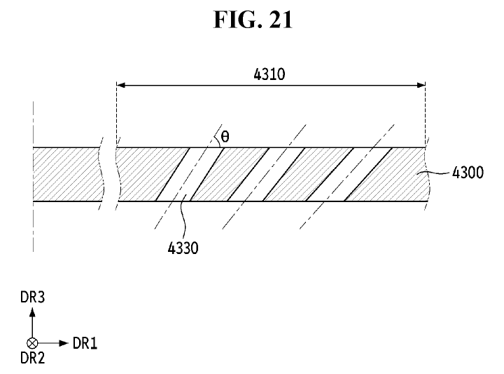

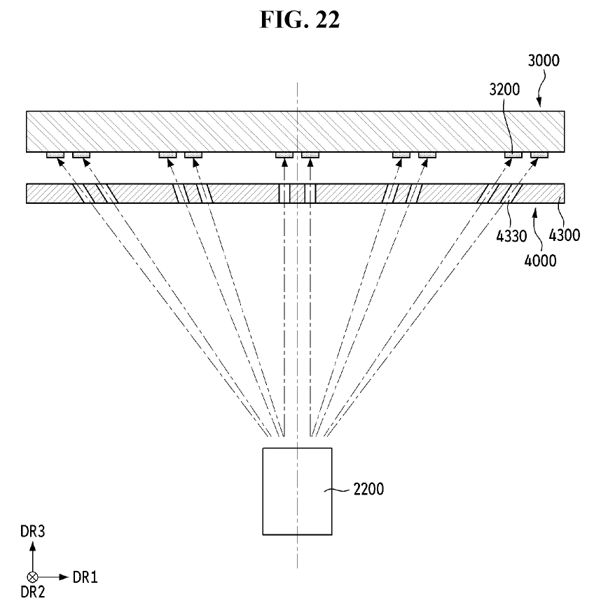

FIG. 20 is a schematic cross-sectional view illustrating the membrane of the deposition mask shown in FIG. 17. FIG. 21 is a schematic enlarged cross-sectional view illustrating the pixel openings shown in FIG. 20. FIG. 22 is a schematic diagram illustrating a method of forming light-emitting layers on a backplane substrate using the deposition mask shown in FIG. 17.

Referring to FIGS. 20 to 22, according to the disclosure, the pixel openings 4330 may have an axial tilt θ that increases in a direction from the center of the membrane 4300 toward the edge portion of the membrane 4300, that is, in a radial direction of the membrane 4300. In an embodiment, as shown in FIG. 22, a vapor deposition material may be provided from the deposition source 2200 onto the backplane substrate 3000 through the pixel openings 4330, and thus the light-emitting layers 3200 may be formed on the backplane substrate 3000. In an embodiment, as shown in FIG. 22, the deposition source 2200 may be disposed below a center portion of the deposition mask 4000, and the pixel openings 4330 may be tilted in a direction in which the vapor deposition material is provided onto the backplane substrate 3000. That is, each of the pixel openings 4330 may have the axial tilt θ that is the same as the incident angle of the vapor deposition material provided onto the backplane substrate 3000.

In an embodiment, the pixel openings 4330 in each mask cell region 4310 may have the axial tilt θ that gradually increases in the direction from the center of the membrane 4300 toward the edge portion of the membrane 4300, that is, in the radial direction of the membrane 4300. In this case, as shown in FIG. 21, a gap between upper portions of the pixel openings 4330 may be greater than a gap between lower portions of the pixel openings 4330 in each mask cell region 4310. In addition, an axial tilt θ of pixel openings 4330 of a mask cell region 4310 next (adjacent) to the edge portion of the membrane 4300 may be greater than an axial tilt θ of pixel openings 4330 of a mask cell region 4310 next (adjacent) to the center of the membrane 4300.

In an embodiment, the pixel openings 4330 of the membrane 4300 may be defined through an anisotropic etching process. Thus, the pixel openings 4330 may have a substantially constant width in a direction in which each of the pixel openings 4330 extends. The anisotropic etching process for forming the pixel openings 4330 will be described later.

In an embodiment of the disclosure as described above, the incident angle of the vapor deposition material provided onto the backplane substrate 3000 may be approximately the same as or similar to the axial tilt of each of the pixel openings 4330. Therefore, shadow areas may be decreased or removed in the deposition process using the deposition mask 4000. In addition, the pixel position accuracy (“PPA”) and the size uniformity of the light-emitting layers 3200 may be greatly improved.

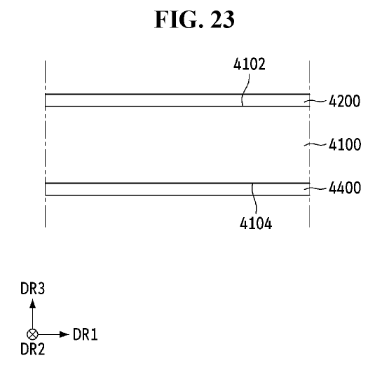

FIGS. 23 to 29 are diagrams illustrating a method of manufacturing a deposition mask according to the disclosure.

FIG. 23 is a schematic cross-sectional view illustrating the formation of a buffer inorganic film and an intermediate inorganic film.

Referring to FIG. 23, the buffer inorganic film 4200 may be formed on the mask substrate 4100. In an embodiment, the mask substrate 4100 may include single crystal silicon. In an embodiment, a single crystal silicon substrate having a thickness in the range of about 700 μm to about 800 μm, e.g., about 725 μm or about 775 μm, may be used as the mask substrate 4100.

The buffer inorganic film 4200 may include silicon oxide (SiOx) and may be formed with a thickness of about 0.2 μm to about 2 μm on the front surface 4102 of the mask substrate 4100 through a thermal oxidation process, for example. In addition, the intermediate inorganic film 4400 may be formed on the rear surface 4104 of the mask substrate 4100. In an embodiment, the intermediate inorganic film 4400 may include silicon oxide (SiOx). In an embodiment, the intermediate inorganic film 4400 may be formed simultaneously with the buffer inorganic film 4200 by a thermal oxidation process. In this case, the intermediate inorganic film 4400 may include the same material as that of the buffer inorganic film 4200 and may have the same thickness as the buffer inorganic film 4200.

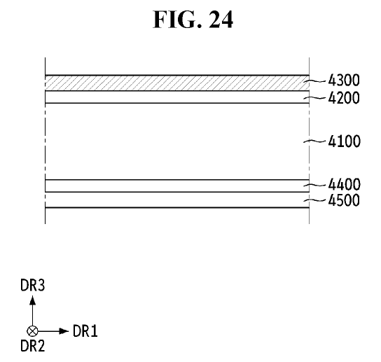

FIG. 24 is a schematic cross-sectional view illustrating formation of a membrane and a rear inorganic film.

Referring to FIG. 24, the membrane 4300 may be formed on the buffer inorganic film 4200. In an embodiment, the membrane 4300 may include silicon nitride (SiNx) and may be formed by a CVD process. In an embodiment, a silicon source gas, such as monosilane (SiH₄), disilane (Si₂H₆), or dichlorosilane (“DCS”) (SiH₂Cl₂), and a nitrogen source gas, such as N₂ or NH₃, may be supplied onto the buffer inorganic film 4200, and the membrane 4300 may be formed with a thickness of about 0.3 μm to about 3 μm by a reaction between the silicon source gas and the nitrogen source gas.

The rear inorganic film 4500 may be formed on the intermediate inorganic film 4400. The rear inorganic film 4500 may include silicon nitride (SiNx) and may be formed by a CVD process. In an embodiment, the membrane 4300 and the rear inorganic film 4500 may be formed simultaneously by a CVD process. In this case, the rear inorganic film 4500 may include the same material as that of the membrane 4300 and may have the same thickness as the membrane 4300.

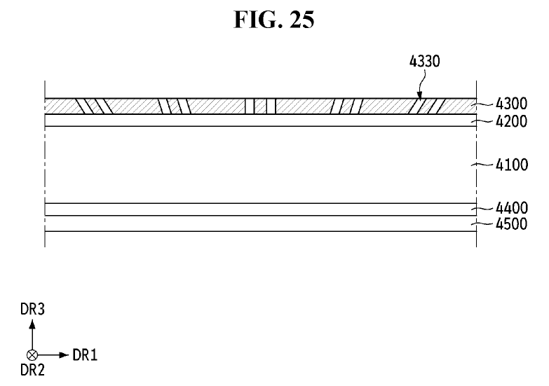

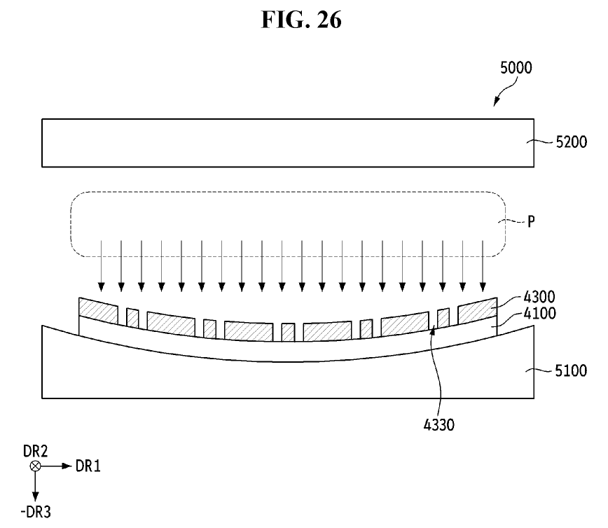

FIG. 25 is a schematic cross-sectional view illustrating an operation of defining pixel openings. FIG. 26 is a schematic diagram illustrating an etching apparatus for defining pixel openings.

Referring to FIGS. 25 and 26, the membrane 4300 may be partially removed to define the pixel openings 4330 penetrating the membrane 4300. In an embodiment, the pixel openings 4330 may be defined to have the axial tilt θ (refer to FIG. 21) that increases in the direction from the center of the membrane 4300 toward the edge portion of the membrane 4300, e.g., in the radial direction of the membrane 4300.

In an embodiment, after forming a photoresist pattern (not shown), which exposes portions where the pixel openings 4330 will be defined, on the membrane 4300, the pixel openings 4330 penetrating the membrane 4300 may be defined by performing an anisotropic dry etching process, e.g., a reactive ion etching (RIE) process, using the photoresist pattern as an etching mask. That is, the RIE process may be performed until the buffer inorganic film 4200 is exposed. The photoresist pattern may be removed by an ashing and/or strip process after the pixel openings 4330 are defined.

In an embodiment, as shown in FIG. 26, an etching apparatus 5000 for performing the RIE process may include a chuck 5100 on which the mask substrate 4100 is placed and a plasma source 5200 disposed above the chuck 5100 to form plasma P. In an embodiment, when the membrane 4300 includes silicon nitride (SiNx), the RIE process may be performed using a first reactive gas, such as CF₄, C₂F₄, C₂F₆, C₃F₆, C₃F₈, C₄F₆, C₄F₈, CH₃F, CH₂F₂, C₂HF₅, CHF₃, NF₃, or SF₆, including or consisting of fluorine, a second reactive gas, such as O₂, NO, or NO₂, including or consisting of oxygen, and a sputtering gas, such as He, Ne, Ar, or Xe, until the buffer inorganic film 4200 is exposed. In this case, the buffer inorganic film 4200 may function as an etch stop film in the RIE process. In an embodiment, a conductively coupled plasma (“CCP”) source, an inductively coupled plasma (“ICP”) source, a transformer coupled plasma (“TCP”) source, or the like may be used as the plasma source 5200, and an electrostatic chuck may be used as the chuck 5100.

In an embodiment, the RIE process may be performed in a state which the mask substrate 4100 is bent, such that the membrane 4300 becomes concave, and accordingly, the pixel openings 4330 may be defined in a central axis direction of the mask substrate 4100. In an embodiment, as shown in FIG. 26, the chuck 5100 may have a top surface with a concave central portion. Accordingly, the mask substrate 4100 placed on the chuck 5100 may be bent into a smile shape due to its own weight. In addition, after the mask substrate 4100 is placed on the chuck 5100, the chuck 5100 may hold the mask substrate 4100 using an electrostatic force to maintain the mask substrate 4100 in a bent state. In an embodiment, the top surface of the chuck 5100 may have a predetermined curvature such that the central portion of the top surface of the chuck 5100 is disposed several millimeters lower than the edge portion of the top surface of the chuck 5100.

In another embodiment, although not shown, the etching apparatus (also referred to as an RIE device) 5000 may include a pusher (not shown) that presses downward the central portion of the mask substrate 4100 after the mask substrate 4100 is placed on the chuck 5100, such that the central portion of the mask substrate 4100 contacts the central portion of the top surface of the chuck 5100. In this case, after the central portion of the mask substrate 4100 contacts the central portion of the top surface of the chuck 5100 by the pusher, the chuck 5100 may hold the mask substrate 4100 using an electrostatic force.

In an embodiment, the RIE process may be performed in a state which the mask substrate 4100 is bent into a smile shape as described above. In an embodiment, bias power for anisotropic etching may be applied to the chuck 5100. Therefore, the pixel openings 4330 may be defined in a vertical direction, e.g., in a negative third direction -DR3, and may have an approximately constant width in the negative third direction -DR3. As described above, the pixel openings 4330 defined in the negative third direction -DR3 may have the axial tilt θ that gradually increases in the radial direction of the membrane 4300 as shown in FIG. 25 when the mask substrate 4100 is stretched flat. In an embodiment, the curvature of the top surface of the chuck 5100 may be determined based on the size of the mask substrate 4100, the distance between the mask substrate 4100 and the deposition source 2200, or the like. Therefore, the axial tilt θ of the pixel openings 4330 may be approximately the same as or similar to the incident angle of the deposition material provided onto the backplane substrate 3000.

In an embodiment, although not shown, dummy openings (not shown) may be defined to penetrate the grid region 4320 (refer to FIGS. 17 and 18) of the membrane 4300. In an embodiment, the dummy openings may be defined simultaneously with the pixel openings 4330. In this case, the pixel openings 4330 and the dummy openings may have the axial tilt θ that gradually increases in the direction from the center of the membrane 4300 toward the edge portion of the membrane 4300.

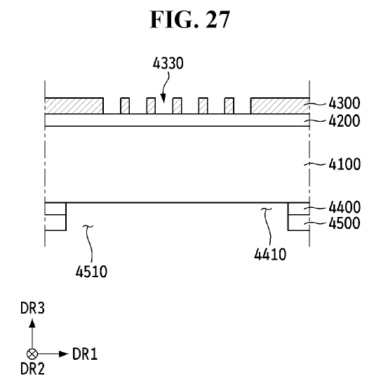

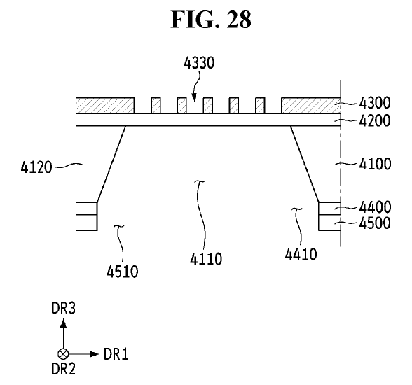

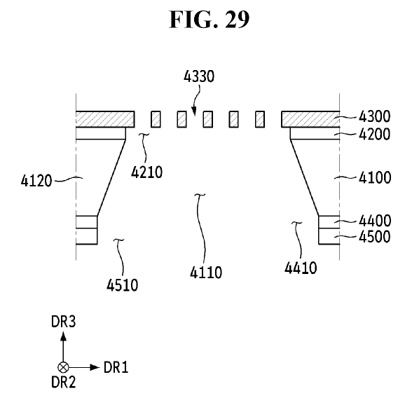

FIG. 27 is a schematic cross-sectional view illustrating an operation of defining an intermediate opening and a rear opening. FIG. 28 is a schematic cross-sectional view illustrating an operation of defining a cell opening. FIG. 29 is a schematic cross-sectional view illustrating an operation of defining a buffer opening.

Referring to FIG. 27, the rear inorganic film 4500 and the intermediate inorganic film 4400 may be partially removed to define the rear openings 4510 and the intermediate openings 4410 that expose rear portions of the mask substrate 4100. In an embodiment, a photoresist pattern (not shown) that exposes portions where the rear openings 4510 are to be defined may be formed on the rear inorganic film 4500, and an anisotropic etching process, e.g., an RIE process, may be performed using the photoresist pattern as an etching mask to define the rear openings 4510 and the intermediate openings 4410. The RIE process may be performed until the rear portions of the mask substrate 4100 are exposed, and the photoresist pattern may be removed by an ashing and/or stripping process after the rear openings 4510 and the intermediate openings 4410 are defined.

Referring to FIG. 28, the mask substrate 4100 may be partially removed to define the cell openings 4110 that expose the buffer inorganic film 4200. In an embodiment, the cell openings 4110 may be defined through an anisotropic etching process using the rear inorganic film 4500 and the intermediate inorganic film 4400 as an etching mask. In an embodiment, the cell openings 4110 may be defined by a wet etching process using an etchant such as a tetramethylammonium hydroxide (“TMAH”) solution or a potassium hydroxide (“KOH”) solution. The wet etching process may be performed until the buffer inorganic film 4200 is exposed, thereby defining the cell openings 4110 that expose the buffer inorganic film 4200 and the rib region 4120 that defines the cell openings 4110.

In an embodiment, the <100> crystal direction of the single crystal silicon substrate used as the mask substrate 4100 may be the third direction DR3, and accordingly, the cell openings 4110 may have a width that gradually decreases from the rear surface 4104 of the mask substrate 4100 toward the front surface 4102 of the mask substrate 4100 by the wet etching process. In an embodiment, inner side surfaces of the cell openings 4110 may have an inclination angle of about 54.7° with respect to the rear surface 4104 of the mask substrate 4100.

In an embodiment, the buffer inorganic film 4200 may function as an etch stop film during an operation of defining the cell openings 4110. In an embodiment, when the buffer inorganic film 4200 is omitted, the etchant may be provided onto the front surface 4102 of the mask substrate 4100 through the pixel openings 4330, and hydrogen bubbles may be generated in the pixel openings 4330 by a reaction between the etchant and the mask substrate 4100. In this case, the mask cell regions 4310 of the membrane 4300 may be damaged by the hydrogen bubbles. The buffer inorganic film 4200 may prevent an etchant from being provided onto the front surface 4102 of the mask substrate 4100 through the pixel openings 4330, thereby preventing damage to the membrane 4300.

Referring to FIG. 29, portions of the buffer inorganic film 4200 exposed through the cell openings 4110 may be removed, thereby defining the buffer openings 4210 that connect the pixel openings 4330 to the cell openings 4110. In an embodiment, when the buffer inorganic film 4200 includes silicon oxide (SiOx), the buffer openings 4210 may be defined by a wet etching process using an etchant such as buffered oxide etchant (“BOE”) or diluted HF.

In an embodiment, each of the cell openings 4110 may be connected to the plurality of pixel openings 4330 through the buffer opening 4210. The pixel openings 4330 may be defined to have the axial tilt θ that gradually increases in the direction from the center of the membrane 4300 toward the edge portion of the membrane 4300, as shown in FIG. 20. In addition, as shown in FIG. 21, the gap between the upper portions of the pixel openings 4330 connected to each of the cell openings 4110 may be greater than the gap between the lower portions of the pixel openings 4330. As a result, in the deposition process of forming the light-emitting layers 3200 on the backplane substrate 3000, the incident angle of the deposition material provided onto the backplane substrate 3000 may be approximately the same as or similar to the axial tilt θ of the pixel openings 4330, and thus the PPA and the size uniformity of the light-emitting layers 3200 may be greatly improved.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A deposition mask comprising:
a mask substrate; and
a membrane disposed on the mask substrate,
wherein cell openings penetrate the mask substrate,
a plurality of pixel openings penetrate the membrane, and
the plurality of pixel openings has an axial tilt which increases in a direction from a center of the membrane toward an edge portion of the membrane.

2. The deposition mask of claim 1, wherein the membrane comprises mask cell regions respectively arranged on the cell openings,
pixel openings among the plurality of pixel openings are defined in each of the mask cell regions, and
the pixel openings have an axial tilt which gradually increases in the direction from the center of the membrane toward the edge portion of the membrane.

3. The deposition mask of claim 2, wherein in each of the mask cell regions, a gap between upper portions of the pixel openings is greater than a gap between lower portions of the pixel openings.

4. The deposition mask of claim 2, wherein an axial tilt of pixel openings of a mask cell region next to the edge portion of the membrane is greater than an axial tilt of pixel openings of a mask cell region next to the center of the membrane.

5. The deposition mask of claim 1, wherein the plurality of pixel openings has a constant width in an extension direction of each of the plurality of pixel openings.

6. The deposition mask of claim 1, further comprising a buffer inorganic film disposed between the mask substrate and the membrane and having buffer openings connecting the cell openings to the plurality of pixel openings.

7. The deposition mask of claim 1, further comprising a rear inorganic film disposed on a rear surface of the mask substrate,
wherein the membrane is disposed on a front surface of the mask substrate, and
the rear inorganic film has rear openings connected to the cell openings.

8. A method of manufacturing a deposition mask, the method comprising:
forming a membrane on a mask substrate;
defining a plurality of pixel openings penetrating the membrane; and
defining cell openings penetrating the mask substrate,
wherein the plurality of pixel openings has an axial tilt which increases in a direction from a center of the membrane toward an edge portion of the membrane.

9. The method of claim 8, wherein the plurality of pixel openings is defined by an anisotropic etching process.

10. The method of claim 9, wherein the defining the plurality of pixel openings comprises:
bending the mask substrate in a manner in which the membrane becomes concave; and
performing the anisotropic etching process in which the plurality of pixel openings is defined in a central axis direction of the mask substrate.

11. The method of claim 9, wherein during the anisotropic etching process, the mask substrate is supported by a chuck having a top surface with a concave central portion.

12. The method of claim 9, wherein during the anisotropic etching process, the chuck holds the mask substrate using an electrostatic force.

13. The method of claim 9, wherein the plurality of pixel openings has a constant width in an extension direction of each of the plurality of pixel openings.

14. The method of claim 8, further comprising forming a buffer inorganic film on the mask substrate,
wherein the membrane is formed on the buffer inorganic film.

15. The method of claim 14, further comprising defining buffer openings connecting the cell openings to the plurality of pixel openings by partially removing the buffer inorganic film.

16. The method of claim 15, wherein each of the cell openings is connected to pixel openings among the plurality of pixel openings, and
the pixel openings have an axial tilt which gradually increases in the direction from the center of the membrane toward the edge portion of the membrane.

17. The method of claim 15, wherein each of the cell openings is connected to pixel openings among the plurality of pixel openings, and
a gap between upper portions of the pixel openings is greater than a gap between lower portions of the pixel openings.

18. The method of claim 8, further comprising forming a rear inorganic film having rear openings on a rear surface of the mask substrate,
wherein the membrane is formed on a front surface of the mask substrate, and
the cell openings are defined by an etching process using the rear inorganic film as an etching mask.

19. An electronic device comprising:
a display panel comprising:
a backplane substrate; and
a plurality of light-emitting layers formed on the backplane substrate by a deposition mask, the deposition mask comprising:
a mask substrate; and
a membrane disposed on the mask substrate,
wherein cell openings penetrate the mask substrate,
pixel openings penetrate the membrane,
the pixel openings have an axial tilt which increases in a direction from a center of the membrane toward an edge portion of the membrane, and
the plurality of light-emitting layers is formed by a deposition process which provides a vapor deposition material through the cell openings and the pixel openings.

20. The electronic device of claim 19, further comprising at least one of a processor, a memory, and a power module.
